(19) United States
(12) Patent Application Publication
(10) Pub. No.: US 2015/0108064 A1
(43) Pub. Date: Apr. 23, 2015

(54) Production Of Channel Type Cyclodextrin Crystals

(71) Applicant: Amphidex A/S, DK-9220 Aalborg Ø (DK)

(72) Inventors: Kim Lambertsen Larsen, Aalborg SV (DK); Ronnie Nielsen, Aalborg (DK); Thuy Thanh Do, Aalborg (DK)

(21) Appl. No.: 14/383,891

(22) PCT Filed: Mar. 13, 2013
(86) PCT No.: PCT/DK2013/050067

§ 371 Date: Sep. 8, 2014

(30) Foreign Application Priority Data
Mar. 13, 2012 (DK) PA 2012 70112

(51) Int. Cl. C30B 7/08; C08B 37/16; C30B 29/60; B01D 15/20; C30B 29/58; C30B 29/66

(52) U.S. Cl. CPC C30B 7/08; C30B 29/58; C30B 29/66; C30B 29/605; B01D 15/20; C08B 37/0012
USPC 210/502.1; 428/36.5; 117/68; 536/103

(57) ABSTRACT

The present invention relates to channel type cyclodextrin crystals, particularly channel type β-cyclodextrin crystals, to a method for producing channel type cyclodextrin crystals, and products comprising channel type cyclodextrin crystals.

### TECHNICAL FIELD OF THE INVENTION

The present invention relates to channel type cyclodextrin crystals. In particular the present invention relates to a method for producing channel type cyclodextrin crystals, and products comprising channel type cyclodextrin crystals.

### BACKGROUND OF THE INVENTION

Cyclodextrins (CD) are renowned for their ability to form inclusion complexes with a wide variety of molecules. This ability to form inclusion complexes with guest molecules and forming a complex with new properties have been used in a wide range of applications and in numerous systems. The most investigated system is aqueous systems containing solubilized CD with an apolar guest molecule which forms the basic driving force for the formation of a complex. Often the goal is to achieve an inclusion complex with increased aqueous solubility compared to the solubility of the apolar guest, which is able to deliver the guest molecule to a recipient. This form of system is used to deliver increased doses of vitamins in soft drinks while masking any unwanted flavor. It is also used to solubilize a medicine for increased bioavailability as well as achieving larger doses in the blood without precipitation.

A less investigated CD system is solid CD crystals and their properties. In solid form, CD is found in three different forms with two of them being crystalline (cage and channel type) and the last being amorphous. The study of the different crystal forms and their different abilities is a relatively new research area within the CD research field. Rusa et al. (2002) have produced channel type α-cyclodextrin crystals by recrystallization. α-CD (1.825 g) was dissolved in 12.5 mL of deionized water, while continuously stirring at 50° C. for 1 h. The clear solution of α-CD (50° C.) was then quickly poured into 50 mL of chloroform (room temperature), while moderately stirring. The white precipitate was immediately vacuum-filtered and allowed to dry overnight directly in the Buchner funnel under vacuum draft. Recrystallization of α-CD by precipitation into stirred acetone did not result in channel type CD. Furthermore, the procedure with chloroform results in a precipitate with a considerable amount of cage type crystals present. Additionally, the solvents used are highly toxic and not considered suitable for industrial use.

A similar recrystallization procedure was applied to γ-CD. This time, 1.8 g (or 11.6 g) of γ-CD was dissolved in 8 mL (or 50 mL) of deionized water, while stirring at 50° C. for 15 h. The γ-CD solution was then added drop wise into 50 mL (or 300 mL) of stirred acetone at room temperature. After vacuum filtration, the white powder was air-dried directly in the Buchner funnel. Again, the solvent used is highly toxic and not considered suitable for industrial use.

The successful production of channel type crystals of β-cyclodextrin has not been reported.

The uses of solid CD crystals are suitable in the gas phase and in liquids in which the solid CD crystals are insoluble. The use of CD in an organic solvent in which solid CD crystals is insoluble has been investigated in a number of publications. Kida et al. (2008) have proven the suitability of solid CD crystals for complete removal of chlorinated aromatic compounds from insulating oil. In the study Kida et al. (2008) uses channel type crystals of γ-CD.

Hence, an improved method for the production of channel type crystals of CD would be advantageous.

### SUMMARY OF THE INVENTION

Thus, it is an object of the present invention to provide a method that solves the above mentioned problems of the prior art.

Thus, one aspect of the invention relates to a method for producing channel type cyclodextrin crystals comprising the steps of:

a) Providing a solution of cyclodextrin;
b) Contacting said solution with a non-solvent system having a Snyder polarity index (P′) of less than 5.4 to precipitate channel type cyclodextrin;
c) Separating said precipitated channel type cyclodextrin from the solution and non-solvent system;
provided that when the cyclodextrin is an α-cyclodextrin, and when the non-solvent system does not comprise an alcohol, the non-solvent system has a relative polarity of less than 0.229;
provided that when the cyclodextrin is an β-cyclodextrin, and when the non-solvent system does not comprise an alcohol, the non-solvent system has a relative polarity of less than 0.164;
provided that when the cyclodextrin is a γ-cyclodextrin, the non-solvent system is selected from the group consisting of ethanol, 1-propanol, 1-butanol and mixtures thereof.

Another aspect of the present invention is a channel type β-cyclodextrin crystal characterised by at least the following X-ray powder diffractogram reflexes:

| Angle | Rel. int |
|---|---|
| [°] | [%] |
| 6.21 | 66.4 |
| 7.24 | 100.0 |
| 9.74 | 19.7 |
| 10.09 | 53.2 |
| 11.96 | 51.3 |
| 12.22 | 45.5 |
| 18.80 | 43.8 |

Another aspect of the present invention relates to channel type cyclodextrin crystals obtainable by the method according to the method of the present invention.

Yet another aspect of the present invention is to provide a thermoplastic polyester container comprising a thermoplastic polyester and a channel type cyclodextrin crystal obtainable by the method according to the method of the present invention.

Another aspect of the present invention is to provide a filter material comprising channel type cyclodextrin crystals obtainable by the method of the present invention.

Still another aspect of the present invention is to provide a filter mask comprising channel type cyclodextrin crystals obtainable by the method of the present invention.

One aspect of the present invention is to provide a food packaging product comprising channel type cyclodextrin crystals obtainable by the method of the present invention.

### BRIEF DESCRIPTION OF THE FIGURES

FIG. 1 shows X-ray diffraction diffractograms of as-received α-CD (cage structure) (a), the α-CD obtained crystals made in chloroform and dried in air (b) air-dried under vacuum (c). The arrows under (a) show the characteristic peaks of cage structure, where the arrows under (c) show the characteristic peaks of channel type structure of α-CD. Reproduced from (Langmuir 2002; 18(25):10016-10023),

FIG. 2 shows X-ray diffraction diffractograms of as-received γ-CD (cage structure) (a), the γ-CD obtained crystals made in acetone and dried in air (b) air-dried under vacuum (c). The arrows under (a) show the characteristic peaks of cage structure, where the arrow under (b) shows the characteristic peak of channel type structure of γ-CD. Reproduced from (Langmuir 2002; 18(25):10016-10023),

FIG. 3 shows X-ray diffractograms of α-CD crystals obtained by precipitation of α-CD aqueous solution with a concentration of 140 g/L in eight different organic solvents. For comparison as-received (pure) α-CD was also measured,

FIG. 4 shows X-ray diffractograms of β-CD crystals obtained by precipitation of β-CD aqueous solution with a concentration of 35 g/L in eight different organic solvents. For comparison as-received (pure) β-CD was also measured,

FIG. 5 shows X-ray diffractograms of γ-CD crystals obtained by precipitation of γ-CD aqueous solution with a concentration of 180 g/L in eight different organic solvents. For comparison as-received (pure) γ-CD was also measured,

FIG. 6 shows X-ray diffractograms of α-CD crystals obtained by precipitation of α-CD aqueous solution in Pentane and THF. On the figure the first temperature in the parenthesis is the temperature of the aqueous CD solution and the second temperature is the temperature of the Pentane or THF, where “RoomT” refers to room temperature,

FIG. 7 shows X-ray diffractograms of γ-CD crystals obtained by precipitation of γ-CD aqueous solution in Pentane and THF. On the figure the first temperature in the parenthesis is the temperature of the aqueous solution CD and the second temperature is the temperature of the solvent, where “RoomT” referees to room temperature,

FIG. 8 shows X-ray diffractograms of γ-CD crystals obtained by precipitation of γ-CD aqueous solution in acetone and ethanol. On the figure the first temperature in the parenthesis is the temperature of the aqueous solution CD and the second temperature is the temperature of the solvent, where “RoomT” referees to room temperature,

FIG. 9 shows X-ray diffractograms of α-CD products obtained by quick cooling of oversaturated 50° C. α-CD solution and α-CD solution with channel crystals seeded in solution (-s), in liquid nitrogen, ice-bath, and room temperature. Different concentrations of α-CD were tested where products 26-28 have a concentration of 200 g/L, 46-48 have a concentration of 250 g/L, and product 81 and 82 have CD concentration of 400 and 500 g/L, respectively,

FIG. 10 shows X-ray diffractograms of β-CD products obtained by quick cooling of oversaturated 50° C. β-CD solution, in liquid nitrogen, ice-bath, and room temperature. The β-CD solution had a concentration of 60 g/L in all experiments,

FIG. 11 shows X-ray diffractograms of β-CD products obtained by quick cooling of oversaturated 50° C. β-CD solution and β-CD solution with channel crystals seeded in solution (-s), in liquid nitrogen, ice-bath, and room temperature,

FIG. 12 shows a 1D ¹H NMR spectrum of channel type α-CD crystals produced using pentane dissolved in DMSO,

FIG. 13 shows the molar solvent residue per mol channel type α-CD crystals shown as a function of their vapor pressure,

FIG. 14 shows the absorption of toluene by cage and channel type α-CD crystals. “Cage-CD” means as-received cage CD crystals where e.g. “38 Channel-CD in Pentane” is product 38 containing channel type α-CD crystals produced in pentane. Five headspace vials with toluene without α-CD was tested to insure a correct starting signal for each experiment,

FIG. 15 shows absorption of toluene by channel type α-CD crystals. “Cage-CD” means as-received cage CD crystals where e.g. “38 Channel-CD in Pentane” is product 38 containing channel type α-CD crystals produced in pentane. Five headspace vials with toluene without α-CD was tested to insure a correct starting signal for each experiment,

FIG. 16 shows absorption of toluene by cage and channel type γ-CD crystals “Cage-CD” means as-received cage CD crystals where e.g. “50 Channel-CD in Pentane” is product 50 containing channel type γ-CD crystals produced in pentane. Five headspace vials with toluene without γ-CD was tested to insure a correct starting signal for each experiment,

FIG. 17 shows absorption of toluene by cage and channel type γ-CD crystals. “Cage-CD” means as-received cage CD crystals where e.g. “50 Channel-CD in Pentane” is product 50 containing channel type γ-CD crystals produced in pentane. Five headspace vials with toluene without γ-CD was tested to insure a correct starting signal for each experiment,

FIG. 18 shows the release of pentane during the absorption of toluene from product 50 produced in pentane. Pentane residues were released into gas phase while toluene was removed from gas phase. The pentane was not quantified,

FIG. 19 shows absorption of four guest molecules by channel type α-, and γ-CD crystals. “50 Channel γ-CD in Pentane” is product 50 containing channel type γ-CD crystals produced in pentane. Four different guest molecules; 1-butanol (A), methyl acetate (B), myrcene (C), and limonene (D) were measured to test the selectivity of CD. Pure guest is measured to insure correct starting signal (e.g. 1-butanol). Each experiment was repeated three times with the standard deviation shown on the curves,

FIG. 20 shows the results of five guest molecules added into a vial containing different amount of channel type γ-CD crystals producing in ethanol and pentane. Channel crystals obtained in pentane show as empty marker while the fill markers belong to channel crystal producing in ethanol,

FIG. 21 shows the results of α- and γ-CD channel type crystals tested with the same guest molecules, where both channel type crystals have been produced in pentane. The marker is filled for α-CD and the marker is empty for γ-CD,

FIG. 22 shows the absorption rate of cage and channel type structure of γ-CD. Toluene 1 and Toluene 2 were measured the same day with cage and channel γ-CD, respectively, to insure correct starting signal, where the amount of CD is listed in the brackets,

FIG. 23 shows a UV-Vis spectrum of iodine and spectra of 4 mM of α-CD with iodine in different concentrations, and

FIG. 24 shows a UV-Vis spectrum of the diluted cage and product 64 containing channel α-CD complex with iodine in different concentration of α-CD at 4 mM and 2 mM,

FIG. 25 shows an X-ray diffractogram of α-CD channel crystals obtained by precipitation of α-CD aqueous solution in dioxane with and without PEG. The products were heated in a 105° C. oven for different time periods. For comparison as-received (pure) α-CD was also measured. The arrows show the characteristic peaks,

FIG. 26 shows an X-ray diffractogram of α-CD channel crystals obtained by precipitation of α-CD aqueous solution in pentane with and without PPG. For comparison as-received (pure) α-CD was also measured. The arrows show the characteristic peaks,

FIG. 27 shows an X-ray diffractogram of α-CD channel crystals obtained by precipitation of α-CD aqueous solution in pentane with and without PPG. For comparison as-received (pure) α-CD was also measured. The products were heated in a 105° C. oven for different time periods,

FIG. 28 shows an X-ray diffractogram of α-CD channel crystals obtained by precipitation of α-CD aqueous solution in pentane with and without glucose. For comparison as-received (pure) α-CD was also measured. The products were heated in a 105° C. oven for different time periods,

FIG. 29 shows an X-ray diffractogram of α-CD channel crystals obtained by precipitation of α-CD aqueous solution in THF with and without glucose. For comparison as-received (pure) α-CD was also measured. The products were heated in a 105° C. oven for different time periods,

FIG. 30 shows an X-ray diffractogram of α-CD channel crystals obtained by precipitation of α-CD aqueous solution in THF with and without glucose. For comparison as-received (pure) α-CD was also measured. The products were heated in a 105° C. oven for different time periods,

FIG. 31 shows an X-ray diffractogram of γ-CD channel crystals obtained by precipitation of γ-CD aqueous solution in pentane with and without PEG. For comparison as-received (pure) α-CD was also measured. The products were heated in a 105° C. oven for different time periods,

FIG. 32 shows an X-ray diffractogram of γ-CD channel crystals obtained by precipitation of γ-CD aqueous solution in ethanol with and without PPG. For comparison as-received (pure) α-CD was also measured. The products were heated in a 105° C. oven for different time periods,

FIG. 33 shows an X-ray diffractogram of γ-CD channel crystals obtained by precipitation of γ-CD aqueous solution in ethanol with and without PPG. For comparison as-received (pure) α-CD was also measured. The products were heated in a 105° C. oven for different time periods,

FIG. 34 shows an X-ray diffractogram of α-CD channel crystals obtained by precipitation of α-CD aqueous solution in THF with and without glucose. For comparison as-received (pure) α-CD was also measured. The products were heated in a 105° C. oven for different time periods,

FIG. 35 shows an X-ray diffractogram of γ-CD channel crystals obtained by precipitation of γ-CD aqueous solution in ethanol with and without glucose. The products were heated in a 105° C. oven for different time periods.

FIG. 36 shows X-ray diffractograms of α-CD crystals obtained by precipitation of α-CD aqueous solution with a concentration of 140 g/L in five different organic solvents. For comparison as-received (pure) α-CD was also measured,

FIG. 37 shows X-ray diffractograms of α-CD crystals obtained by precipitation of α-CD aqueous solution with different concentrations denoted as the last number e.g. 136 α-CD in pentane 50, where 50 is 50 g/L. For comparison as-received (pure) α-CD was also measured,

FIG. 38 shows X-ray diffractograms of α-CD crystals obtained by precipitation of α-CD aqueous solution with a concentration of 170 g/L denoted as the last number in ethanol, acetone, and methanol. For comparison as-received (pure) α-CD was also measured,

FIG. 39 shows X-ray diffractograms of α-CD crystals obtained by precipitation of α-CD aqueous solution with different concentrations denoted as the last number where the number in bracket is the volume ratio between α-CD solution and ethanol e.g. 145 α-CD in Ethanol (1:12) 170, where (1:120) is 10 ml CD solution was dropped in 120 ml ethanol, and 170 is 170 g/L For comparison as-received (pure) α-CD was also measured,

FIG. 40 shows X-ray diffractograms of β-CD crystals obtained by precipitation of β-CD aqueous solution with a concentration of 80 g/L in six different organic solvents. For comparison as-received (pure) β-CD was also measured,

FIG. 41 shows X-ray diffractograms of β-CD crystals obtained by precipitation of β-CD aqueous solution with a concentration of 80 g/L in seven different organic solvents. For comparison as-received (pure) β-CD was also measured,

FIG. 42 shows X-ray diffractograms of β-CD crystals obtained by precipitation of β-CD aqueous solution with different concentrations denoted as the last number e.g. 155 β-CD in 1-Propanol 40, where 40 is 40 g/L. For comparison as-received (pure) β-CD was also measured,

FIG. 43 shows X-ray diffractograms of β-CD crystals obtained by precipitation of β-CD aqueous solution with different concentrations denoted as the last number number where the number in bracket is the volume ratio between β-CD solution and ethanol e.g. 169 β-CD in Ethanol (1:15) 100, where (1:150) is 10 ml CD solution was dropped in 150 ml ethanol and 100 is 100 g/L. For comparison as-received (pure) β-CD was also measured,

FIG. 44 shows X-ray diffractograms of γ-CD crystals obtained by precipitation of γ-CD aqueous solution with a concentration of 180 g/L in five different organic solvents. For comparison as-received (pure) γ-CD was also measured,

FIG. 45 shows X-ray diffractograms of γ-CD crystals obtained by precipitation of γ-CD aqueous solution with different concentrations denoted as the last number e.g. 166 γ-CD in Ethanol 50, where 50 is 50 g/L. The γ-CD solutions used had different concentration as shown as a number in the end. For comparison as-received (pure) γ-CD was also measured,

FIG. 46 shows absorption of toluene by cage and channel type β-CD crystals. “Cage β-CD” means as-received cage β-CD crystals where e.g. “Channel β-CD in 1-Propanol” is product containing channel type β-CD crystals produced in 1-Propanol.

FIG. 47 shows absorption of 33.8 μmol benzene by 38.6 μmol channel type β-CD crystals. The absorptions were repeated 7 times in all, after each time the channel crystals were ventilated in fume hood for different times which are shown in the figure. The first ventilation time is 30.5 hour where the last ventilation time is 28 hours.

FIG. 48 shows absorption of 33.8 μmol benzene by 35.7 μmol I channel type γ-CD crystals. The absorptions were repeated 7 times in all, after each time the channel crystals were ventilated in fume hood for different times which are shown in the figure. The first ventilation time is 30.5 hour where the last ventilation time is 28 hours.

FIG. 49 shows absorption of 18.78 μmol toluene by channel type β-CD crystals with and without limonene. Different amounts of channel crystals were used, from 5 to 100 mg corresponding to around 4 to 80 μmol of the CD crystal. The absorption of channel crystals without limonene is higher because their cavity is not filled with limonene molecules.

FIG. 50 shows that during absorption of toluene, shown in FIG. 49, limonene molecules were released by channel type β-CD crystals with limonene.

FIG. 51 shows an X-ray powder diffractogram of the channel type β-cyclodextrin crystals of the present invention at the 2θ (°) angle.

The present invention will now be described in more detail in the following.

### DETAILED DESCRIPTION OF THE INVENTION

The terms “cyclodextrin” and “CD” are used interchangeably throughout this application. The CD is made up of ring bound 1,4 α-linked glucopyranose units. The number of glucopyranose determines the type of cyclodextrin, with the most common having 6, 7 or 8 units called α-, β- and γ-CD, respectively.

Though their structure seems similar except for the size, the three different CD have different properties. A small overview of their properties is presented in Table 1.

TABLE 1
The properties of α, β and γ CD.

| | | | Cavity | | | | |
|---|---|---|---|---|---|---|---|
| | | | diameter | | Solu- | | |
| | | Outer | [nm] | | bility | | |
| Cyclo- | M_{w} | diameter | Inner | Outer | [g/kg | Hydrate H₂O | |
| dextrin | [g/mol] | [nm] | rim | rim | H₂O] | Cavity | external |
| α CD | 972 | 1.52 | 0.45 | 0.53 | 145 | 2.0 | 4.4 |
| β CD | 1134 | 1.66 | 0.60 | 0.65 | 18.4 | 6.0 | 3.6 |
| γ CD | 1296 | 1.77 | 0.75 | 0.85 | 232 | 8.8 | 5.4 |

As seen from Table 1, the different CD have varying properties with the most remarkable being the different solubility and their number of hydration H₂O. The different properties cannot be explained from size alone as the size goes in the order of α, β and then γ CD whereas the solubility goes β, α and then γ CD. The explanation for the different solubilities is found in the hydroxyl groups present in the CD and their special arrangement. The narrow end is composed of the C6 primary hydroxyl groups of the individual glucopyranose molecules, which have free rotation and thereby result in the formation of the narrow end. The narrow end is denoted the primary end. The wider end is composed of the secondary hydroxyl groups of the individual glucopyranose molecules, which means that there are twice as many hydroxyl groups in the wider end. The wide end is called the secondary end. The inside of the CD cavity of all three types of CD is more hydrophobic than water despite the molecule having a very large number of hydroxyl groups. The hydrophobicity comes from the cyclic nature of the CD where the hydroxyl groups are placed on the “rim” of the CD with the more hydrophobic hydrogen in the centre of the CD.

The unique chemical structure of CD enables them to form inclusion complexes with a wide variety of small molecules, as well as oligomer, polymer, and aromatic molecules.

Complex formation is due to several types of driving forces, such as Van der Waals interactions or hydrophobic interactions between the cyclodextrin cavity and the hydrophobic moiety of the guest, electrostatic interaction, and release of high energy water from the cavity in the complex formation process. Hence the complex formation of CD and a hydrophobic guest would be very difficult in a non-polar organic solvent. One of the main driving forces for complexation is the unfavourable interaction between water and the hydrophobic cavity which results in a release of energy when water is displaced by the guest molecule. With a non-polar organic solvent the main driving force for complexation is removed and therefore the complexation is less efficient which is why most literature on CD are on aqueous systems.

The size of guest molecules also contributes to the formation of CD inclusion complexes because of the steric effect. Consequently, the stability of CD inclusion complexes is based on the binding forces between the CD cavity and the incorporated guest molecules. The binding forces depend on the polarity of the guests, temperature, and the medium where the complexes are present. A guest molecule with a polarity lower than that of water can easier form complex with CD in aqueous solution. Therefore the stability of a CD inclusion complex will increase with the increasing hydrophobicity of the guest molecule.

The ability to form complexes of CD has increasingly been used in a wide range of industrial applications, such as controlled release of drug, odour and volatility, increasing solubility of low soluble guest in aqueous media, enhancing stability of guests against the degradation effects of heat, light, and oxidation, and covering unwanted odours. For that reason, CDs have been used in textile-, food-, cosmetics-, pharmacology-, and chemical industry. In the textile industry, CDs are used to stabilize the colours of clothing, e.g. CD complexes with dye molecules in aqueous solution have been used as a retarder by controlling the dye concentration that is absorbed by a textile. In the food- and pharmaceutical industry, CDs are used to remove cholesterol from dairy products, mask different unwanted odours, and eliminate undesired tastes and smells e.g. mask bitter flavour of hesperidin in juice. In the chemical industry, CDs have been used in separation and purification of industrial products where it is applied in stationary phases in gas chromatography (GC) and high performance liquid chromatography (HPLC) because of the CDs ability to distinguish between isomeric compounds, as well as different functional groups. For these applications, CDs are usually dissolved in an aqueous solution and then form inclusion complexes with guest molecules or the CDs are chemically bonded to another material e.g. silica gel or polymer.

The use of solid CDs in different crystalline structures has only been investigated on a much smaller scale, especially as solid form in gas phase. The crystalline structure of CDs consists of two major types described as cage- and channel type structures, where the cage type is most stable. The cage type comprises two crystalline arrangements, “herringbone” and “brick-wall”, where both ends of the cavity are “blocked” by adjacent CDs. In the channel type structure, the CDs are stacked in a columnar form and stabilized by hydrogen bonding between the peripheral hydroxyls. The CD molecules in the channel structure are arranged either “head-to-head” or “head-to-tail” and forming many long columns in the crystal. The “head-to-head” structure is formed when either a C2-OH or a C3-OH from one CD bond to either a C2-OH or a C3-OH from the above CD and the C6-OH from the CD bond to the C6-OH from the CD underneath. Either a C2-OH or a C3-OH bonds to a C6-OH the structure, making a “head-to-tail” structure.

As mentioned, the study of solid CD such as the abilities of crystal forms is a new topic in CD research. The use of solid CD crystals in an organic solvent was investigated by Kida et al. (2008). It was proven that channel-type γ-CD crystals can remove chlorinated aromatic compounds from oil while the cage type γ-CD crystal cannot.

In addition, the studies of channel type CD formation are very limited, especially the formation of channel type CD crystals in different organic solvents. The formation of channel type α- and γ-CD crystals by precipitation of aqueous CD in chloroform and acetone, respectively, was studied by Rusa et al. (2002).

The present invention relates to the production of channel type CD crystals.

In order to investigate channel type CD crystals and their formation, basic understanding of crystal formation is necessary. Crystal formation is described by two different mechanisms: nucleation and crystal growth. No crystal will be formed if one of the two is not present during the precipitation, re-crystallization, or cooling.

After the nucleation, the nuclei grow to crystals, and the growth mechanism determines the final morphology of the crystal.

As mentioned before, CD molecules can form different crystal structures like cage and channel structures. Different crystal structures with the same chemical composition are known as polymorphs which can be detected by X-ray diffraction (XRD). In order to understand how the different polymorphs are formed and why only one of them is the ultimately stable phase, the metastable theory will be employed.

A metastable phase, which can exist based on the law of thermodynamics, can become the stable one when the local minimum of the energy vs. order curve is obtained by a crystal structure. Often many different metastable states might exist for a compound but only one of these states is the ultimately stable one. Metastable phases can become the ultimately stable phase only by going through increasingly stable metastable phases until it ultimately end up in the equilibrium phase, as stated by Ostwalds stage rule. Due to a local energy minimum on Gibbs free energy, the transition phase will fall into a metastable phase when it tries to go to ultimate stable phase depending on the energy available in the system. Consequently, only one type of crystal form of all the crystal polymorphs is ultimately stable. The transformation of the metastable phase to the stable phase requires activation energy (ΔF) from the plot of an order (φ) vs. free energy plot (F). The order parameter describes the order of the crystal phase, meaning that the most stable phase is the most ordered phase.

Cage type CD crystals are the most stable crystals (ultimately stable crystals). Consequently, if the cage crystals are the stable phase the channel type CD crystals must be the metastable phase. Hence, CD crystals with cage structure are more ordered than channel structure. If the activation energy is very low, channel type CD crystal should rapidly transform from channel to cage structure.

These phenomena might explain the different stability of different structures of CD crystals (cage and channel type crystals of α, β, and γ-CD). The ultimately stable crystals formed have higher melting temperatures than the metastable crystals, though some parameters can make the true melting temperature of crystals difficult to determine by experiments. This is because the energy barrier of decomposition of metastable phase is smaller than that of the stable polymorph. However, if the channel type CD crystal has no or small activation energy between the cage type and channel type phases, the crystal will almost always be in the stable phase (or cage structure). This might influence why some types of CD form channel crystals easier than other forms of CD.

One object of the present invention is to provide novel methods for production of channel type CD crystals.

One aspect of the present invention relates to a method for producing channel type cyclodextrin crystals comprising the steps of:

a) Providing a solution of cyclodextrin;
b) Contacting said solution with a non-solvent system having a Snyder polarity index (P′) of less than 5.4 to precipitate channel type cyclodextrin;
c) Separating said precipitated channel type cyclodextrin from the solution and non-solvent system;
provided that when the cyclodextrin is an α-cyclodextrin, and when the non-solvent system does not comprise an alcohol, the non-solvent system has a relative polarity of less than 0.229;
provided that when the cyclodextrin is an β-cyclodextrin, and when the non-solvent system does not comprise an alcohol, the non-solvent system has a relative polarity of less than 0.164;
provided that when the cyclodextrin is a γ-cyclodextrin, the non-solvent system is ethanol, 1-propanol, 1-butanol, and mixtures thereof.

A second aspect of the present invention relates to a method for producing channel type γ-cyclodextrin crystals comprising the steps of:

a) Providing a solution of γ-cyclodextrin;
b) Contacting said solution with a non-solvent system having a Snyder polarity index (P′) of less than 5.4 to precipitate channel type γ-cyclodextrin;
c) Separating said precipitated channel type γ-cyclodextrin from the solution and non-solvent system;
wherein the non-solvent system is an alcohol or mixtures of such, such as ethanol, 1-propanol and 1-butanol.

A third aspect of the present invention relates to a method for producing channel type α-cyclodextrin crystals comprising the steps of:

a) Providing a solution of α-cyclodextrin;
b) Contacting said solution with a non-solvent system having a Snyder polarity index (P′) of less than 5.4 to precipitate channel type α-cyclodextrin;
c) Separating said precipitated channel type α-cyclodextrin from the solution and non-solvent system;
wherein the non-solvent system comprises an alcohol.

A fourth aspect of the present invention relates to a method for producing channel type α-cyclodextrin crystals comprising the steps of:

a) Providing a solution of α-cyclodextrin;
b) Contacting said solution with a non-solvent system having a Snyder polarity index (P′) of less than 5.4 to precipitate channel type α-cyclodextrin;
c) Separating said precipitated channel type α-cyclodextrin from the solution and non-solvent system;
wherein the non-solvent system does not comprise an alcohol and the non-solvent system has a relative polarity of less than 0.229.

A fifth aspect of the present invention relates to a method for producing channel type β-cyclodextrin crystals comprising the steps of:

a) Providing a solution of β-cyclodextrin;
b) Contacting said solution with a non-solvent system having a Snyder polarity index (P′) of less than 5.4 to precipitate channel type β-cyclodextrin;
c) Separating said precipitated channel type β-cyclodextrin from the solution and non-solvent system;
wherein the non-solvent system comprises an alcohol.

A sixth aspect of the present invention relates to a method for producing channel type β-cyclodextrin crystals comprising the steps of:

a) Providing a solution of β-cyclodextrin;
b) Contacting said solution with a non-solvent system having a Snyder polarity index (P′) of less than 5.4 to precipitate channel type β-cyclodextrin;
c) Separating said precipitated channel type β-cyclodextrin from the solution and non-solvent system;
wherein the non-solvent system does not comprise an alcohol and has a relative polarity of less than 0.164.

A seventh aspect of the invention relates to a method for producing channel type cyclodextrin crystals comprising the steps of:

a) Providing a solution of cyclodextrin;
b) Contacting said solution with a non-solvent system having a Snyder polarity index (P′) of less than 5.4 to precipitate channel type cyclodextrin;
c) Separating said precipitated channel type cyclodextrin from the solution and non-solvent system;
provided that when the cyclodextrin is an α-cyclodextrin and when the non-solvent system comprises an alcohol, the non-solvent system has a relative polarity of less than 0.800;
provided that when the cyclodextrin is an α-cyclodextrin, and when the non-solvent system does not comprise an alcohol, the non-solvent system has a relative polarity of less than 0.229;
provided that when the cyclodextrin is an β-cyclodextrin and when the non-solvent system comprises an alcohol, the non-solvent system has a relative polarity of less than 0.800;
provided that when the cyclodextrin is an β-cyclodextrin, and when the non-solvent system does not comprise an alcohol, the non-solvent system has a relative polarity of less than 0.164;
provided that when the cyclodextrin is a γ-cyclodextrin, the non-solvent system is ethanol.

A Snyder polarity index is a relative measure of the degree of interaction of the solvent with various polar test solutes (Snyder L. R. “Classification of the Solvent Properties of Common Liquids,” Journal of Chromatography Science, 16: 223, (1978), incorporated herein by reference).

As used herein, the term “solution of cyclodextrin” refers to any liquid matter or mixtures of liquid matters comprising dissolved cyclodextrin. Hence, the liquid matter or mixtures of liquid matters are considered a solvent of cyclodextrins.

In one embodiment, the solution comprises liquid matter being a protic solvent or mixtures of protic solvents. A protic solvent is a chemical compound comprising a hydrogen atom bound to an electronegative atom such as an oxygen and a nitrogen. Thus, a protic solvent typically includes a hydroxyl group and/or an amino group. In one embodiment the liquid matter is a solvent or mixture of solvents wherein the solubility of cyclodextrin is more than 1 gram per litre at 20 degrees Celsius such as a solubility of more than 5 grams per litre in the non-solvent system at 20 degrees Celsius, such as more than 10 grams per litre at 20 degrees Celsius.

In a preferred embodiment, the protic solvent contains at least one hydroxyl group. Suitable protic solvents include, for example, water, methanol, ethanol, n-propanol, propane-2-diol and glycerol, ethylene glycol, propylene glycol, propane-1,3-diol, butane-1,4-diol, 2-butene-1,4-diol, and the like, or mixtures of two or more such glycols.

In one embodiment, the solution of cyclodextrin comprises solvents selected from the group consisting of water, methanol, ethanol and mixtures thereof.

In another embodiment, the solution of cyclodextrin comprises water.

Preferably, the solution of cyclodextrin is an aqueous solution of cyclodextrin.

As used herein, the term “non-solvent system” refers to a liquid matter or a mixture of liquid matters wherein the cyclodextrin has a solubility of less than 10 grams per litre at 20 degrees Celsius.

In one embodiment, the cyclodextrin has a solubility of less than 5 grams per litre in the non-solvent system at 20 degrees Celsius, such as less than 1 gram per litre at 20 degrees Celsius.

In another embodiment, the solution of cyclodextrin is saturated or supersaturated.

Saturation is the point at which a solution of a substance, in this case CD, can dissolve no more of that substance and additional amounts of it will appear as a precipitate. This point of maximum concentration, the saturation point, depends on the temperature of the liquid as well as the chemical nature of the substances involved. Hence, the saturation degree is different for different types of CDs.

The term “supersaturation” refers to a solution that contains more of the dissolved material than could be dissolved by the solvent under the solubility amount. Supersaturated solutions are prepared or result when some condition of a saturated solution is changed, for example increasing temperature, decreasing volume of the saturated Liquid (as by evaporation), or increasing pressure.

Supersaturation may be the driving force for a solution crystallization process. Crystallization scientists gain control over crystallization process and product quality by carefully controlling the prevailing level of supersaturation during the process. Supersaturation is critical because it is the driving force for crystal nucleation and growth. Nucleation is the birth of new crystal nuclei—either spontaneously from solution (primary nucleation).

In one embodiment, the concentration of the solution of cyclodextrin is at least 10% of the saturation point at 20 degrees Celsius, such as within the range of 20-100% of the saturation point, e.g. 30%, such as within the range of 40-95% of the saturation point, e.g. 50%, such as within the range of 60-90% of the saturation point, e.g. 70%, such as within the range of 75-85% of the saturation point, e.g. 80% of the saturation point at 20 degrees Celsius.

In another embodiment, the temperature of the solution of cyclodextrin is at or above 0 degrees Celsius, such as within the range of 5-200 degrees Celsius, e.g. 10 degrees Celsius, such as within the range of 15-190 degrees Celsius, e.g. 20 degrees Celsius, such as within the range of 25-180 degrees Celsius, e.g. 30 degrees Celsius, such as within the range of 35-170 degrees Celsius, e.g. 40 degrees Celsius, such as within the range of 45-160 degrees Celsius, e.g. 50 degrees Celsius, such as within the range of 55-150 degrees Celsius, e.g. 60 degrees Celsius, such as within the range of 65-140 degrees Celsius, e.g. 70 degrees Celsius, such as within the range of 75-130 degrees Celsius, e.g. 80 degrees Celsius, such as within the range of 85-120 degrees Celsius, e.g. 90 degrees Celsius, such as within the range of 95-110 degrees Celsius, e.g. 100 degrees Celsius.

In still another embodiment, the temperature of the solution of cyclodextrin is equal to or higher than the temperature of the non-solvent system.

Surprisingly it was found that different non-solvent systems worked for the production of α-, β-, γ-channel type CD crystals. The production of channel type CD crystals by precipitation in a broad range of organic solvents (i.e. non-solvent systems) is successful in the order γ-CD>>α-CD>β-CD. It is believed that channel type γ-CD crystals are more easily formed because γ-CD has a more flexible structure compared to α- and β-CD, while the high solubility in water gives the possibility of making high concentration γ-CD aqueous solutions which contributes to higher precipitation rate during addition (e.g. drop wise) to the non-solvent system.

Channel type α-CD crystals were shown to be produced in pentane, hexane, heptane, cyclohexane, 1-butanol, 1-propanol, 1,4-dioxane, THF, ethyl acetate, and chloroform. The first eight solvents gave very pure channel type crystals as found from the diffractograms whereas ethyl acetate and chloroform resulted in less pure channel type crystals (see examples section).

Also certain alcohols, such as 1-propanol and 1-butanol were shown to work, however, methanol did not.

As can be deducted from the tables in the examples section, when the cyclodextrin is an α-cyclodextrin, the non-solvent system must have a Snyder polarity index (P′) of less than 5.4.

Surprisingly, the inventors have found that when the cyclodextrin is an α-cyclodextrin, and when the non-solvent system does not comprise an alcohol, the non-solvent system must have a relative polarity of less than 0.229.

In order to provide very pure channel type crystals without significant contamination of cage type crystals, the non-solvent system, when not comprising an alcohol, must furthermore have a relative polarity of less than 0.207, preferably having a value of 0.164 (1,4-dioxane) or lower (e.g. pentane and heptane).

Values for relative polarity have been extracted from: Christian Reichardt, Solvents and Solvent Effects in Organic Chemistry, Wiley-VCH Publishers, 3rd ed., 2003.

The relative polarity for selected alcohols is as follows (value in parenthesis): 1-butanol (0.586), 2-butanol (0.502), i-butanol (0.552), t-butyl alcohol (0.786), cyclohexanol (0.509), ethanol (0.654), 1-heptanol (0.549), 1-hexanol (0.559), methanol (0.762), 1-octanol (0.537), 1-pentanol (0.568), 2-pentanol (0.488), 3-pentanol (0.463), 1-propanol (0.617), and 2-propanol (0.546).

In one embodiment, when the cyclodextrin is an α-cyclodextrin, the non-solvent is selected from the group consisting of 1-butanol, 2-butanol, i-butanol, t-butyl alcohol, cyclohexanol, ethanol, 1-heptanol, 1-hexanol, 1-octanol, 1-pentanol, 2-pentanol, 3-pentanol, 1-propanol, 2-propanol and mixtures thereof. Preferably, ethanol is provided as a mixture with another non-solvent.

In another embodiment, when the cyclodextrin is an α-cyclodextrin, the non-solvent is selected from the group consisting of 1-butanol, 2-butanol, i-butanol, t-butyl alcohol, cyclohexanol, 1-heptanol, 1-hexanol, 1-octanol, 1-pentanol, 2-pentanol, 3-pentanol, 1-propanol, 2-propanol and mixtures thereof.

In one embodiment, when the cyclodextrin is an α-cyclodextrin, the non-solvent system has a Snyder polarity index (P′) of less than 5.4, such as within the range of 0-4.5, e.g. within the range of 0-4, such as within the range of 0-3.5, e.g. within the range of 0-3, such as within the range of 0-2.5, e.g. within the range of 0-2, such as within the range of 0-1.5, e.g. within the range of 0-0.5.

In one embodiment, when the cyclodextrin is an α-cyclodextrin, wherein the non-solvent system does not comprise an alcohol, the non-solvent system has a Snyder polarity index (P′) of less than 5.4, and a relative polarity of less than 0.229, such as a relative polarity within the range of 0-0.164, e.g. 0-0.150, such as a relative polarity within the range of 0-0.140, e.g. 0-0.130, such as a relative polarity within the range of 0-0.120, e.g. 0-0.110, such as a relative polarity within the range of 0-0.100, e.g. 0-0.090, such as a relative polarity within the range of 0-0.080, e.g. 0-0.070, such as a relative polarity within the range of 0-0.060, e.g. 0-0.050, such as a relative polarity within the range of 0-0.040, e.g. 0-0.030, such as a relative polarity within the range of 0-0.020, e.g. 0-0.010, such as a relative polarity within the range of 0-0.009, e.g. 0-0.008, such as a relative polarity within the range of 0-0.080, e.g. 0-0.070.

In one embodiment, the cyclodextrin in the solution of cyclodextrin is an α-cyclodextrin and the non-solvent system is selected from the group consisting of pentane, hexane, heptane, cyclohexane, ethanol, 1-butanol, 1-propanol, THF, ethyl acetate, 1,4-dioxane and mixtures thereof. Preferably, ethanol is provided as a mixture with another non-solvent.

In analogy with the α-cyclodextrin, as can be deducted from the tables in the examples section, when the cyclodextrin is a β-cyclodextrin, the non-solvent system must have a Snyder polarity index (P′) of less than 5.4.

However, surprisingly, the inventors have found that when the cyclodextrin is an β-cyclodextrin, and when the non-solvent system does not comprise an alcohol, the non-solvent system must have a relative polarity of less than 0.164.

In one embodiment, when the cyclodextrin is a β-cyclodextrin, the non-solvent system has a Snyder polarity index (P′) of less than 5.4, such as within the range of 0-4.5, e.g. within the range of 0-4, such as within the range of 0-3.5, e.g. within the range of 0-3, such as within the range of 0-2.5, e.g. within the range of 0-2, such as within the range of 0-1.5, e.g. within the range of 0-0.5.

In another embodiment, when the cyclodextrin is a β-cyclodextrin, wherein the non-solvent system does not comprise an alcohol, the non-solvent system has a Snyder polarity index (P′) of less than 5.4, and a relative polarity of less than 0.164, such as a relative polarity within the range of 0-0.163, e.g. 0-0.150, such as a relative polarity within the range of 0-0.140, e.g. 0-0.130, such as a relative polarity within the range of 0-0.120, e.g. 0-0.110, such as a relative polarity within the range of 0-0.100, e.g. 0-0.090, such as a relative polarity within the range of 0-0.080, e.g. 0-0.070, such as a relative polarity within the range of 0-0.060, e.g. 0-0.050, such as a relative polarity within the range of 0-0.040, e.g. 0-0.030, such as a relative polarity within the range of 0-0.020, e.g. 0-0.010, such as a relative polarity within the range of 0-0.009, e.g. 0-0.008, such as a relative polarity within the range of 0-0.080, e.g. 0-0.070.

In one embodiment, when the cyclodextrin is a β-cyclodextrin, the non-solvent is selected from the group consisting of 1-butanol, 2-butanol, i-butanol, t-butyl alcohol, cyclohexanol, ethanol, 1-heptanol, 1-hexanol, 1-octanol, 1-pentanol, 2-pentanol, 3-pentanol, 1-propanol, 2-propanol and mixtures thereof. Preferably, ethanol is provided as a mixture with another non-solvent.

In still another embodiment, when the cyclodextrin is a β-cyclodextrin, the non-solvent system is selected from the group consisting of pentane, hexane, heptane, cyclohexane, ethanol, 1-propanol, 1-butanol and mixtures thereof. Preferably, ethanol is provided as a mixture with another non-solvent.

A reason which can explain the difficulty in producing channel type α- and β-CD crystals is that the channel type crystals are metastable crystals. The transformation of the metastable phase (channel structure) to the stable phase (cage structure) requires activation energy. For the channel type β-CD crystals, the activation energy required might be very small, therefore the channel structure of β-CD in metastable phase will easier end in the ultimately stable crystal phase (cage structure). The activation energy required to transform from metastable phase to stable phase of α-CD may be higher than β-CD which explains the increased stability as well as the increased number of solvents that yield α-CD channel crystals. The rigid structure of β-CD may influence the formation of channel structure of β-CD; it might demand more energy to organize molecules into channel structure, compared to the other CD types.

The results of γ-CD prove that channel type γ-CD crystals could be formed in a broad range of non-solvent systems; although with varying success (ethyl acetate is e.g. is not optimal for the formation of channel type γ-CD crystals.)

One object of the present invention is to reduce the production costs for the channel type γ-CD crystals. The inventors solved this problem by rendering the purification step after the precipitation unnecessary. This was done by selecting a non-toxic non-solvent system. Ethanol, tetraglycol, 1-propanol, 1-butanol, and 1,2-propanediol are non-toxic and convenient solvents. If the channel type CD crystals can be produced in these solvents, the purification step of the products will be unnecessary which would be an economic advantage in an industrial upscale of the production. However, the inventors found that when the non-solvent system is soluble in water, it must have a viscosity suitable for separating the α-, β-, or γ-channel type CD crystals from the non-solvent system. This was difficult when the non-solvent system was tetraglycol or 1,2-propanediol, both having a dynamic viscosity above 50 cP (centipoise) at room temperature (20-25 degrees Celsius). Hence, ethanol, 1-propanol and 1-butanol showed to be more successful.

In still another embodiment, when the cyclodextrin is a γ-cyclodextrin, the non-solvent system is selected from the group consisting of ethanol, 1-propanol, 1-butanol and mixtures thereof.

In one embodiment, the non-solvent system is selected from the group consisting of ethanol, 1-propanol, 1-butanol and mixtures thereof.

As can be deducted from the experimental section, the absorption ability of channel type CD crystals depends on which solvent was used for production.

The toluene absorption ability from best to worst of the channel type α-CD crystals is in the order: chloroform, THF, ethyl acetate, pentane, and dioxane.

The toluene absorption ability from best to worst of the channel type γ-CD crystals is in the order: methanol, ethanol, dioxane, pentane, acetone, THF, chloroform, and ethyl acetate.

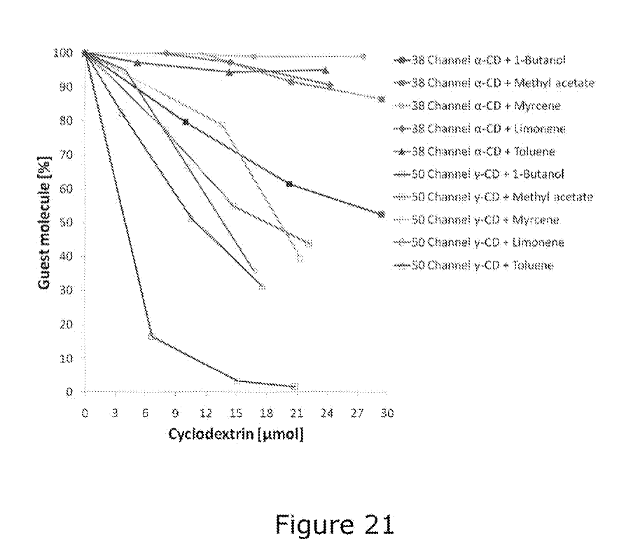

The selectivity of channel type α-CD crystals is very limited compared to channel type γ-CD crystals produced in the same solvent, as seen in FIG. 21.

In another embodiment, the non-solvent system comprises a triglyceride.

In still another embodiment, the non-solvent system is a vegetable oil or a mineral oil (light mixtures of alkanes in the C15 to C40 range).

In yet another embodiment, the non-solvent system is a petroleum product.

In still another embodiment, the cavities of the cyclodextrins are empty or only filled with solvent and/or non-solvents.

In still another embodiment, the pH of the non-solvent system is above 7.

Another aspect relates to channel type cyclodextrin crystals obtainable by the method according to the present invention.

Yet another aspect relates to a channel type β-cyclodextrin crystal characterised by at least the following X-ray powder diffractogram reflexes:

| Angle | Rel. int |
|---|---|
| [°] | [%] |
| 6.21 | 66.4 |
| 7.24 | 100.0 |
| 9.74 | 19.7 |
| 10.09 | 53.2 |
| 11.96 | 51.3 |
| 12.22 | 45.5 |
| 18.80 | 43.8 |

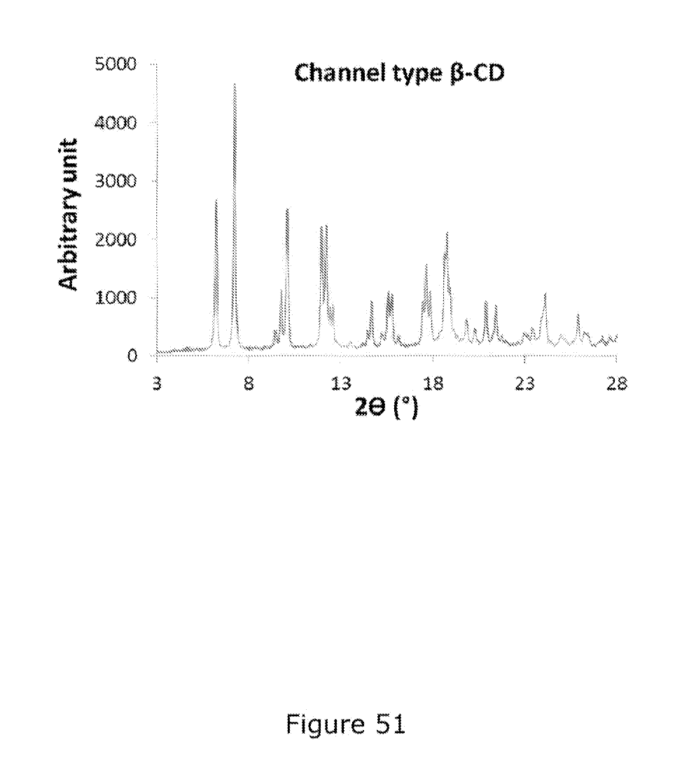

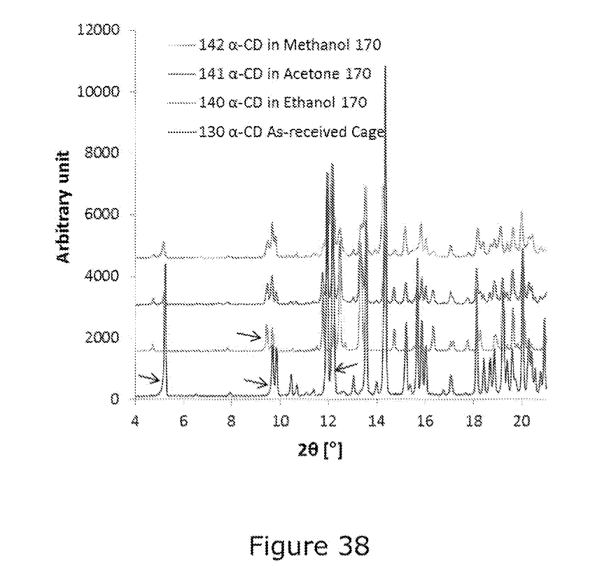

Preferably the β-cyclodextrin crystal is a channel type β-cyclodextrin crystal having a powder x-ray diffraction pattern essentially as shown in FIG. 51.

Preferably said channel type β-cyclodextrin crystal does not comprise a stabiliser. Preferably said channel type β-cyclodextrin crystal is not in the form of an inclusion complex.

Activated carbon is a popular odor adsorbent because it is very effective and inexpensive. However, it is black in color, picks up moisture, is brittle (i.e. has low mechanical tolerance), and, when heated or saturated with odor, can surrender some or its entire adsorbed odor. The present invention solves this problem by the use of channel type cyclodextrin crystals instead of activated carbon in various applications, such as removal of end-products.

Some end-products to be removed are aldehydes, free fatty acids, free radicals, ketones, hydrogen sulfide, and polyphenol by-products. The end-products can be present in the headspaces of packages of snack foods, crackers and cookies, cereal, pet foods, rice, powdered dairy products, cooking oils, coffee, and soaps.

One aspect relates to a fiber comprising channel type cyclodextrin crystals of the present invention or obtainable by the method according to the present invention.

In one embodiment, the fibre is a component of a woven or non-woven fabric.

Another aspect relates to a thermoplastic polyester container comprising a thermoplastic polyester and a channel type cyclodextrin crystal of the present invention or obtainable by the method according to the present invention.

Yet another aspect relates to a filter material comprising channel type cyclodextrin crystals of the present invention or obtainable by the method according to the present invention.

Another aspect relates to a filter mask comprising channel type cyclodextrin crystals of the present invention or obtainable by the method according to the present invention.

Still another aspect relates to channel type cyclodextrin crystals of the present invention or obtainable by the method according to the present invention for use as a medicament.

Another aspect relates to the use of channel type cyclodextrin crystals of the present invention or obtainable by the method according to the present invention for sorption of iodine.

Another aspect relates to the use of channel type cyclodextrin crystals of the present invention or obtainable by the method according to the present invention for a personal or medical hygiene article.

Another aspect relates to the use of channel type cyclodextrin crystals of the present invention or obtainable by the method according to the present invention as a food or food additive.

One aspect of the present invention is to provide a food packaging product comprising channel type cyclodextrin crystals of the present invention or obtainable by the method of the present invention.

Another aspect relates to a packaging material comprising channel type cyclodextrin crystals of the present invention or obtainable by the method according to the present invention.

Another aspect relates to an aroma barrier comprising channel type cyclodextrin crystals of the present invention or obtainable by the method according to the present invention.

Experiments have shown that the channel type cyclodextrins of the present invention may absorb guest molecules and subsequently release them via ventilation. After ventilation the crystal will re-adsorp guest molecules with similar or slightly reduced efficiency as measured by adsorption percentage.

Thus, another aspect of the present invention is the use of channel type cyclodextrin crystals of the present invention or obtainable by the method according to the present invention as a recyclable absorbent material. Preferably a recyclable adsorbant material which is re-activated using ventilation.

It is well known that CD molecules are capable of slow release or controlled release of guest molecules. This is also the case for the channel type crystals of the present invention.

Thus, yet another aspect of the present invention is the use of channel type cyclodextrin crystals of the present invention or obtainable by the method according to the present invention as a controlled release system.

In addition to controlled release the channel type CD crystals of the present invention are also capable of triggered release of guest molecules. If the cyclodextrin is subjected to a molecule (A) with similar or larger affinity for the host cavity, than an already present guest molecule (B), said guest molecule (B) may be released. Thus, addition of (A) triggers the release of (B). The present inventors have shown that this is possible, e.g. to release limonene molecules from CD crystals by the subjection of said crystals to toluene.

Therefore, another aspect of the present invention is the use of channel type cyclodextrin crystals of the present invention or obtainable by the method according to the present invention as a triggered release system, wherein a trigger molecule triggers the release of a molecule to be released from the cavity of the cyclodextrin. Preferably a triggered release system is provided, wherein the trigger molecule has similar or greater affinity for the cyclodextrin cavity than the molecule to be released, i.e. the guest molecule.

Also the channel type CD crystal of the present invention may advantageously be incorporated in plastic materials or precursors of plastic materials. The CD's may either be used to add adsorbent properties to the plastic material or to host guest molecules for release, e.g. controlled release or triggered release.

Thus another aspect of the present invention is a plastic products comprising the channel type cyclodextrin crystals of the present invention or obtainable by the method according to the present invention. Plastic products may include products and product precursors such as plastic resins, polymer resins and plastic products such as for example packaging material, flexible films, filters, household products, bin liners, bottles, caps, masks, wound dressings and hygiene products.

It should be noted that embodiments and features described in the context of one of the aspects of the present invention also apply to the other aspects of the invention.

All patent and non-patent references cited in the present application, are hereby incorporated by reference in their entirety.

The invention will now be described in further details in the following non-limiting examples.

### EXAMPLES

### Materials

The chemicals that were used for the experiments can be seen in Table 2.

TABLE 2
Data for the chemicals used, including manufacturer and purity
of the chemicals, all sorted alphabetically. When no purity
was given by the manufacture, the purity is not listed.

| | | Minimum |
|---|---|---|
| Chemical | Manufacturer | Purity [%] |
| 1,2-Propanediol | Sigma-Aldrich | 99.5 |
| 1,4-Dioxane | AppliChem | 99 |
| 1-Butanol | Sigma-Aldrich | 99.7 |
| 1-Propanol | Sigma Aldrich | 99 |
| Acetone | Merck | 99.8 |
| Chloroform | J. T. Baker | 99.8 |
| Cyclohexane | Sigma Aldrich | 99 |
| Deuterated-dimethyl | Sigma Aldrich | 99.9 |
| sulfoxide | | |
| Ethanol | Kemetyl | 96 |
| Ethyl acetate | Sigma-Aldrich | 99.5 |
| Heptane | Sigma-Aldrich | 99 |
| Hexane | Sigma-Aldrich | 97 |
| Iodine | Merck | 99.5 |
| Limonene | Sigma-Aldrich | 97 |
| Methanol | Sigma-Aldrich | 99.5 |
| Methyl acetate | Sigma-Aldrich | 99.8 |
| Molecular sieve, 4 Å | Sigma-Aldrich | |
| Myrcene | Fluka | 95 |
| Pentane | Sigma-Aldrich | 99 |
| Tetraglycol | Sigma-life Science | |
| Tetrahydrofuran (THF) | Sigma-Aldrich | 99.9 |
| Toluene | Sigma-Aldrich | 99.9 |
| α-, β-, and γ-cyclodextrin | Wacker Chemie | |

### Wide Angle X-Ray Diffraction

The samples were investigated by means of X-ray diffraction (Panalytical, Almelo, The Netherlands) in alpha configuration equipped with X-celerator detector. Wide-angle XRD (WAXD) measurements were performed in the range of 2° to 40° with step of 0.032° and scan step time of 0.5 seconds. The samples were measured with Cu Kα₁ radiation source on a diffractometer.

The standard setup of XRD

### Gonionneter=PW3050/60 (Theta/2Theta);

Minimum step size 2Theta:0.001;
Minimum step size Omega:0.001
Sample stage=Spinner PW3064
Diffractometer system=XPERT-PRO
Measurement program=2-40°_{—}32 min_{—}0.032,
Intended wavelength type: Kα1

### Kα1 (Å): 1.540598

### Kα2 (Å): 1.544426

Kα2/Kα1 intensity ratio: 0.00

### Kα (Å): 1.540598

### Kβ (Å): 1.392250

Incident beam path Radius (mm): 240.0
X-ray tube Name: PW3373/10 Cu LFF DK305096
Anode material: Cu

### Voltage (kV): 45

### Current (mA): 40

### Focus

Focus type: Line

### Length (mm): 12.0

width (mm): 0.4
Take-off angle (°): 6.0
Monochromator Name: Inc. Beam 1xGe111 Cu/Co (a1 for reflection mode)

### Crystal:

### Name: Ge

### Type: Symmetric

### Shape: Curved

No. of reflections: 1
h k l: 1 1 1
Mask Name: Inc. Mask Fixed 10 mm (MPD/MRD)

### Width (mm): 6.60

Anti-scatter slit Name: Slit Fixed 2°

### Type: Fixed

### Height (mm): 3.03

Divergence slit Name: Prog. Div. Slit
Distance to sample (mm): 140

### Type: Automatic

Irradiated length (mm): 10.0

### Offset (mm): 0.00

Beam knife Name: Beam knife for MPD systems
Sample movement
Movement type: Spinning
Rotation time (s): 2.0
Diffracted beam path Radius (mm): 240.0
Anti-scatter slit

### Name: AS Slit 8.7 mm (X'Celerator)

### Type: Fixed

### Height (mm): 8.70

Soller slit Name: Soller 0.02 rad.

### Opening (rad.): 0.02

### Detector Name: X'Celerator

Type: RTMS detector
PHD—Lower level (%): 34.5
PHD—Upper level (%): 80.0

### Mode: Scanning

Active length (°): 2.122
Source Created by: labficus

### Application SW: X'Pert Data Collector vs. 2.2i

Instrument control SW: XPERT-PRO vs. 2.1A

### Instrument ID: 0000000000005541

Sample mode

### Reflection

### Scan

Scan axis: Gonio
Scan range (°): 2.0000-40.0348
Step size (°): 0.0334
No. of points: 1138
Scan mode: Continuous
Counting time (s): 200.025

### Example 1

### Characterization of Cage and Channel Type CD Crystals

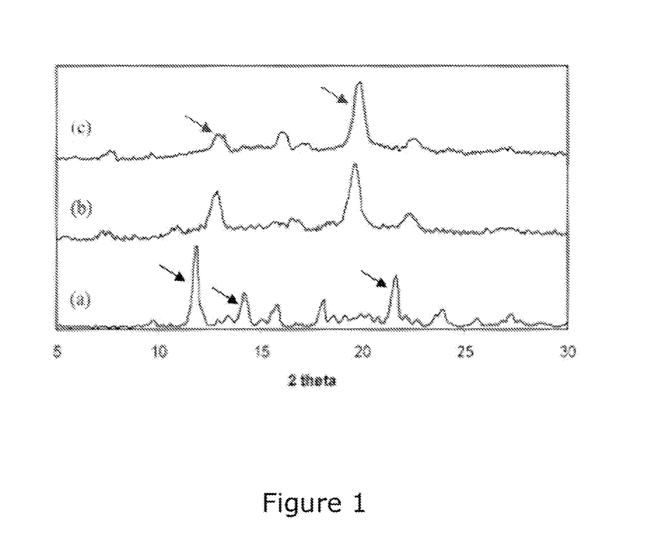

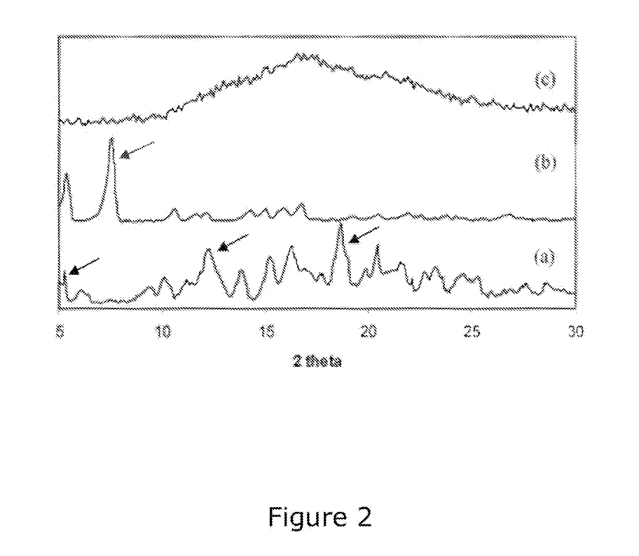

Channel type CD crystals have previously been characterized by use of WAXRD, DSC and TGA. X-Ray diffractograms of channel type α- and γ-CD crystals, which were produced in chloroform and acetone, respectively, and cage type CD from Rusa et al. 2002 can be seen in FIG. 1 and FIG. 2.

The diffraction peaks belonging to cage structure crystals have higher diffraction angle than the diffraction peaks belonging to channel structure. The main peaks of cage type α-CD crystals are placed at 2θ=12.0°, 14.4°, and 21.7° while the channel type structure have the peaks at 2θ=13.2° and 20.0°. The precipitates of α-CD in chloroform still have channel structure although they were dried under vacuum. This indicates that the channel structure of α-CD is more stable than the γ-CD channel type crystals.

FIG. 2 show the cage type γ-CD crystals have the main diffraction peak at 2θ=5.1°, 12.4°, and 18.8° while the characteristic diffraction peak of the channel type structure at 7.5°. The WAXRD diffractogram of the precipitates which were air-dried under vacuum get no peaks, meaning amorphous structure. It has also been found that a lack of water molecule in the cavity results in a collapse of the structure and turns the crystals into an amorphous structure.

β-CD inclusion complexes with polymer have yielded channel structure as studied by Panova et al. 2007. The main diffraction peaks of the cage type β-CD crystal at 2θ=11° and 12.5° whereas the characteristic peaks of the channel structure are located at 2θ=7.2° and 10°.

The present inventors have however formed the more stable channel type β-CD crystals of the present invention without the use of stabilisers or inclusion complexes, using the described novel method. The Channel type β-CD crystals are characterised by at least the following X-ray powder diffractogram reflexes:

| Angle | AVE DEV | Rel. int | AVE DEV |
|---|---|---|---|
| [°2θ] | [°] | [%] | [%] |
| 6.21 | 0.006 | 66.4 | 5.468 |
| 7.24 | 0.007 | 100.0 | 0.000 |
| 9.74 | 0.008 | 19.7 | 2.049 |
| 10.09 | 0.011 | 53.2 | 3.712 |
| 11.96 | 0.005 | 51.3 | 4.282 |
| 12.22 | 0.019 | 45.5 | 4.896 |
| 18.80 | 0.049 | 43.8 | 6.963 |

The diffractogram is depicted in FIG. 51.

### Example 2

### General Procedure for Production of Cyclodextrin (CD) Crystals

Most of the experiments involved precipitation where only the concentration, solvent, temperature or additives were changed. In general the following procedure was used unless deviations are noted under each procedure. A predetermined amount of CD was weighed and added to a 200 mL blue cap flask and deionized water was added to the 200 mL mark, the solution was left with magnetic stirring at 70° C. for at least 3 hours. After desolvation a predetermined amount of the solution was added to an addition funnel where the solvent/water used for precipitation/re-crystallization was cooled to 0° C. The CD solution was added drop wise to the solvent/water under magnetic stirring. After all CD solution was added to the solvent/water, the final solution was filtrated using filter funnel with very low vacuum, note that some solutions were left to rest for an amount of time before precipitates were appeared. The collected precipitate was left to dry overnight in a fume hood. Afterwards, CD crystals powder was grinded to insure the crystals were as small as possible prior to use and stored in closed containers at −18° C.

### Example 3

### Production of Channel Type CD Crystals

The production of channel type CD crystals was performed with different concentrations of CD in aqueous solution. Some CD solutions were oversaturated, but it was insured that these solutions were clear by stirring them at 70° C. for at least 3 hours prior to use. The different types of methods applied to produce CD crystals with channel structure are the following:

1. Precipitation of an aqueous CD solution in an organic solvent (non-solvent system) such as pentane, ethanol, etc. The procedure was carried out using different temperatures of both the CD solution and solvent in order to investigate solvent as well as temperature effect.

2. Precipitation of an oversaturated aqueous CD solution in water.

3. Quick cooling of oversaturated aqueous CD solution in nitrogen, an ice-bath containing NaCl salt with a temperature of −5° C., and room temperature water.

### Example 4

### Production by Precipitation in a Non-Solvent System

As-received, α-, β-, and γ-CD powder was dissolved in deionized water in different concentrations. The water solubility of α-, β-, and γ-CD can be seen below.

TABLE 3
Properties of α-, β-, and γ-CD

| Parameter | α-CD | β-CD | γ-CD |
|---|---|---|---|
| Solubility in water at 25° C. | 14.5 | 1.85 | 23.2 |
| (g/100 mL) | | | |
| Mw [DA] | 972 | 1135 | 1297 |
| Approx. volume of cavity [Å³] | 174 | 262 | 427 |
| Crystal water [wt %] | 10.2 | 13.2-14.5 | 8.13-17.7 |

The solutions were stirred at 70° C. with reflux for 3, 5, and 15 hours for α-, β-, γ-CD, respectively, to ensure no CDs crystals were left in solution. The CD solution was added to the non-solvent system with a volume ratio of 1:5.5 for α- and γ-CD e.g. 10 mL CD solution was dropped into 55 mL non-solvent system but for β-CD the volume ratio was 1:8. The CD precipitates were filtrated with vacuum and afterwards air-dried in the filtration funnel. Various solvents spanning from apolar (e.g. pentane) to polar (e.g. ethanol) were chosen as possible candidates for production of channel type CD. Some of the solvents used and their properties are shown with increasing polarity index in Table 4.

TABLE 4
The solvents arranged according to increasing polarity index. M means miscible
with water. TLV is Threshold Limit Value; it is the maximum safe concentration
in the air where a worker is not affected while exposed daily. The unavailable
data is marked as (—). Values for relative polarity, threshold limits and
vapor pressure have been extracted from: Christian Reichardt, Solvents and Solvent
Effects in Organic Chemistry, Wiley-VCH Publishers, 3rd ed., 2003.

| | | | | | Vapor | |
|---|---|---|---|---|---|---|
| | | | Viscosity | Solubility | pressure | |
| | Polarity | Relative | at 25° C. | in H₂O | at 25° C. | TLV |
| Solvents | Index | polarity | [mPas] | [g/100 g] | [mmHg] | [ppm] |
| Pentane | 0 | 0.009 | 0.224 | 0.004 | 512.25 | 600 |
| Hexane | 0 | 0.009 | 0.3 | 0.001 | 166.5 | 50 |
| Heptane | 0 | 0.012 | 0.387 | 0.003 | 45.675 | 400 |
| Cyclohexane | 0 | 0.006 | 0.894 | 0.005 | 97.5 | 300 |
| 1-butanol | 3.9 | 0.586 | 2.54 | 7.700 | 6.45 | 50 |
| 1-propanol | 4 | 0.617 | 1.945 | M | 20.7 | 200 |
| Chloroform | 4.1 | 0.259 | 0.537 | 0.800 | 196.5 | 10 |
| THF | 4.2 | 0.207 | 0.456 | 30.000 | 162 | 200 |
| Ethyl acetate | 4.3 | 0.228 | 0.423 | 8.700 | 94.5 | 400 |
| 1,4-dioxane | 4.8 | 0.164 | 1.177 | M | 37.125 | 20 |
| Ethanol | 5.2 | 0.654 | 1.074 | M | 59.025 | 1000 |
| Acetone | 5.4 | 0.355 | 0.306 | M | 231 | 500 |
| Methanol | 6.6 | 0.762 | 0.544 | M | 126.75 | 200 |
| Tetraglycol | (—) | (—) | 58 | M | (—) | (—) |
| 1,2-Propanediol | (—) | (—) | 56 | M | (—) | (—) |

The solvents in Table 4 have been used for both industrial and pharmaceutical purposes such as synthesis, food processing, chemical extraction, purification of drugs, and as an eluent in liquid chromatography. Tetraglycol has also been used as pharmaceutical solvent for drug injections. Based on the threshold limit value, the toxicity of chloroform and 1,4-dioxane are highest, but they have still been used in the pharmaceutical industry and therefore channel type CD crystals containing residue of those solvent should be acceptable if the level of the solvent is less than the threshold value. Ethanol, 1-propanol, 1-butanol, tetraglycol, and 1,2-propanediol are non-toxic and convenient solvents, especially ethanol. If the channel type CD crystals can be produced in these solvents, the purification step of the products will be unnecessary which would be an economic advantage in an industrial upscale of the production. Channel type crystals are produced in different solvents because it is believed every solvent can change the thermodynamic driving force for the formation of CD crystals which can influence the crystal structure upon precipitation. The residue of solvent in the channel type crystals after formation might also influence certain properties of the final product, such as the amount of cavities available for formation of inclusion complex as well as the stability of the product.

When the CD solution concentration of α- and γ-CD is below (140 g/L and 180 g/L, respectively) their saturated level, precipitation was observed in the solvents in Table 4. Precipitation was also observed for the oversaturated β-CD solution with 35 g/L in the same solvents. Tetraglycol and 1,2-propanediol were used because of their non-toxic properties as the production of channel type CD crystals would be faster when the purification step is not needed. However, experiments showed that only a very small amount of precipitates were observed after the final mixtures rested for one day. A slow crystallization process will almost always give thermodynamic stable crystals which correspond to cage structure for CD.

With a close to saturated β-CD solution (18 g/L), no precipitates were found in pentane and THF. Therefore the precipitation experiment of β-CD was not continued for the other solvents. The aqueous CD solutions are insoluble in pentane, hexane, heptane, cyclohexane, chloroform, and ethyl acetate. Under magnetic stirring the CD drops were spilt to many smaller droplets due to phase separation; this phenomenon might also influence the precipitation and final crystal structure.

In another experiment, an aqueous α- and γ-CD solution at 70° C. was added drop wise into an ice-cold solvent. This was done in order to investigate the effect of cooling rate, isolated from the solvent effects. The results of the experiments are shown in Table 5. The cooling rate was in the order of: CD solution at 70° C./ice-bath solvent>70° C./room temperature solvent>room temperature/room temperature solvent where the experiments with 70° C. solution and solvent at 0° C. can be seen in Table 5.

TABLE 5
The aqueous CD solutions were precipitated in
the organic solvents. All solvents used were at room temperature and
the CD solution was kept at room temperature or 70° C. during the
precipitation.“Yes” means formation of a precipitate and “no” means
that no precipitate was found initially. The empty rows mean no
experiment was carried out.

| | Conc. [α- | | Conc. [γ- | |
|---|---|---|---|---|
| | CD] | Conc. [α-CD] | CD] | Conc. [γ-CD] |
| Ice-bath | 140 g/L at | 140 g/L at | 180 g/L at | 180 g/L at room |
| solvent | 70° C. | room temp. | 70° C. | temp. |
| Pentane | Yes (p-83) | Yes (p-84) | Yes (p-87) | Yes (p-88) |
| Tetrahydrofuran | Yes (p-85) | Yes (p-86) | Yes (p-89) | Yes (p-90) |
| Acetone | | | Yes (p-91) | Yes (p-92) |
| Ethanol | | | Yes (p-93) | Yes (p-94) |

### Example 5

### Production by Precipitation in Water

Precipitation of α-, β-, and γ-CD solutions in water with volume ratio of 1:3 gave no precipitates, as seen in the Table 6.

TABLE 6
Oversaturated concentrations of CD solutions
were precipitated in the deionized water which wasdrop wise added and
cooled by an ice-bath where the CD solution was kept at 70° C. during
the precipitation. “No” means that no precipitate was found.

| | | Conc. [β- | Conc. [γ- |
|---|---|---|---|
| | Conc. [α-CD] | CD] | CD] |
| | 200 g/L | 60 g/L | 250 g/L |
| Water | No | No | No |

After precipitation, the final concentration of the α-, β-, and γ-CD in solution was 50, 15, and 62.5 g/L, respectively. The concentration of the CD solutions was lower than their maximum solubility at 25° C., as disclosed above; especially the α- and γ-CD solutions. During addition, precipitation was observed with each drop, but the precipitate was dissolved quickly in the large quantity of water. Hence, this method is not suitable for the production of channel type CD crystals.

### Example 6

### Rapid Cooling Aqueous CDs and CDs with Channel Type Seeds in Liquid Nitrogen, Ice-Bath, and Room Temperature Water

20 mL of oversaturated α-, β- and γ-CD solutions were cooled in liquid nitrogen and left for 10 minutes. The same procedure was carried out where precipitation was attempted by cooling at a temperature of −5° C., and at room temperature where the solution was left for 2 hours.

Precipitates were only observed by cooling the oversaturated β- and γ-CD solution in liquid nitrogen, as seen in Table 7 whereas the oversaturated α-CD solutions gave no precipitates. The solutions of α-, β-, and γ-CD which were cooled at a temperature of −5° C., and at room temperature showed no precipitates within 10 minutes. Small precipitates in the solutions appeared after one day and grew rapidly to the next day. This observation corresponds to crystal formation theory; first formation of nuclei, followed by crystal growth.

TABLE 7
Oversaturated concentrations of CD solutions
were cooled in liquid nitrogen, an ice-bath containing NaCl salt with a
temperature of −5° C., and room temperature water, the CD solution was
kept at 50° C. during the cooling. “Yes” means immediately formation of
the precipitate and “No” means that no precipitate was formed initially.
The empty rows mean no experiment was carried out.

| | Conc. [α- | Conc. [α- | | |
|---|---|---|---|---|
| | CD] | CD] | Conc. [β-CD] | Conc. [γ-CD] |
| Cooling in | 200 g/L | 250 g/L | 60 g/L | 250 g/L |
| Liquid nitrogen | No (p-26) | No (p-46) | Yes (p-30) | Yes (p-35) |
| Ice-bath (−5° C.) | No (p-27) | No (p-47) | No (p-31) | No (p-36) |
| Room | No (p-28) | No (p-48) | No (p-32) | |
| temperature | | | | |

The same procedure was repeated, but now an amount of channel type CD crystals was added in the CD solution before the cooling process was undertaken in order to try and make a seeded crystallization. Channel type CD crystals powder was grinded thoroughly to insure the crystals were as small as possible prior to use. All the precipitates were filtered without vacuum through a 0.45 μm filter and left to air-dry for 2 days.

Although the concentration of α- and γ-CD solutions was oversaturated, especially the α-CD solution, as seen in Table 8, the viscosity was not visually effected. It was considered that crystal growth could happen after seeding with CD channel crystals in the solution which should induce channel type CD crystals. The attempted crystal growth could not be observed initially, but after one day many small crystals were present in the solution.

TABLE 8
The channel type CD crystals were added into the
CD solutions as nucleating agents at 50° C. and then cooled in an ice-
bath and room temperature water. The weight ratio between CD in
solution and the channel type CD crystals is abbreviated w/w where p-
40 and p-51, which consists of crystals with channel structure, are
abbreviated for product 40 and 51, respectively. “No” means that no
precipitate was found initially. The empty rows mean no experiment
was carried out.

| | Conc. [α-CD] | Conc. [α-CD] | Conc. [γ-CD] |
|---|---|---|---|
| | 400 g/L + p-40 | 500 g/L + p-40 | 250 g/L + p-51 |
| Cooling in | w/w (1:0.01) | w/w (1:0.05) | w/w (1:0.005) |
| Ice-bath | | | No (p-58) |
| Room temperature | No (p-81) | No (p-82) | No (p-59) |

### Example 7

### Determination of Cage and Channel Structure by X-Ray Diffraction

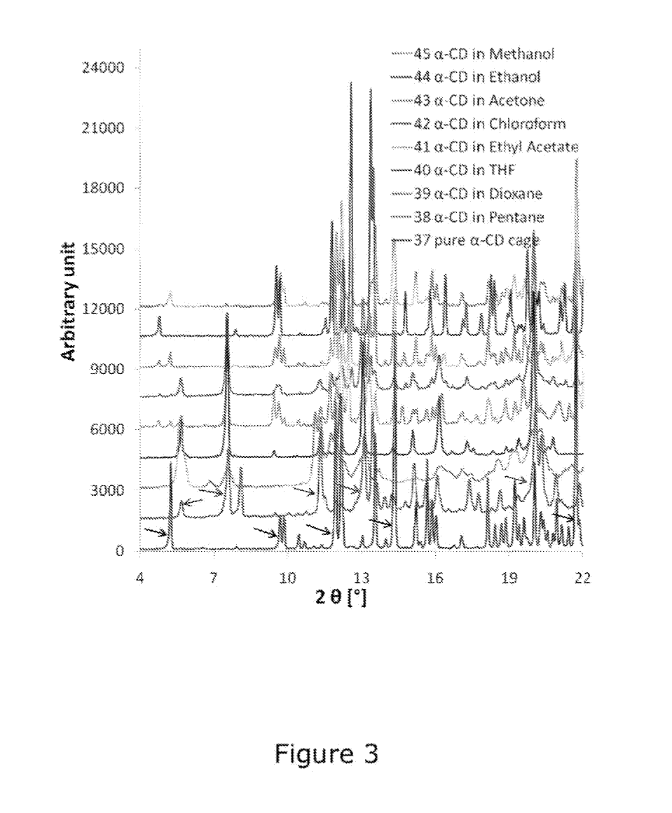

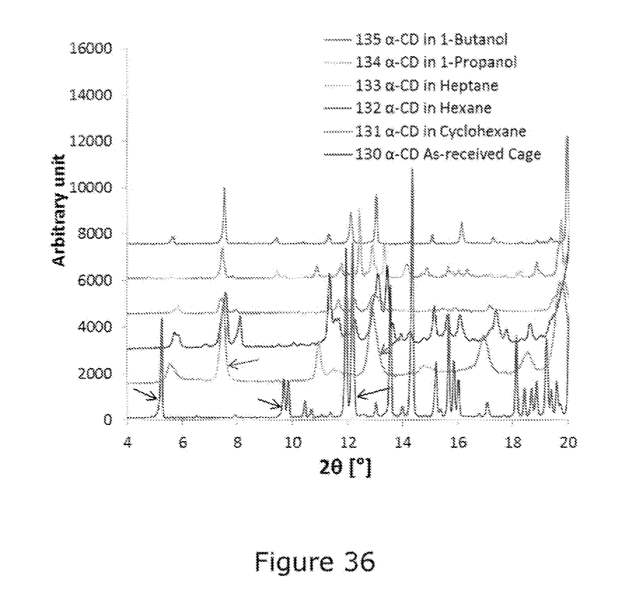

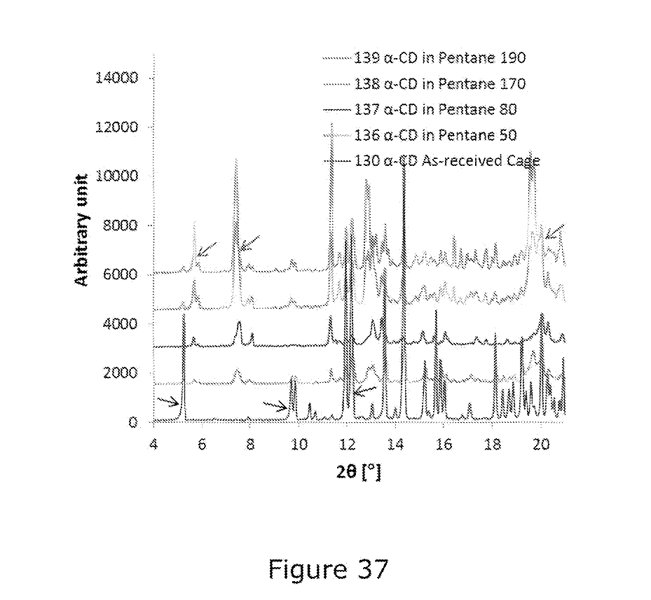

The X-ray diffractograms of the α-CD powders obtained after precipitation from different organic solvents are depicted in FIG. 3, FIG. 36 and FIG. 37. Their diffractograms are evidently different from the as-received (pure-cage) α-CD diffractogram. The main peaks at 2θ=5.3°, 9.7°, 9.8°, 12°, 12.3°, 14.4°, and 21.7° are shown for the as-received α-CD belonging to cage crystalline structure (arrows on the lowest positioned diffractogram in FIG. 1). The peaks at 2θ=5.7°, 7.6°, 11.3°, 13.1°, and 20° that are observed for the α-CD products obtained in pentane, hexane, heptane, cyclohexane, 1-butanol, 1-propanol, 1,4-dioxane, THF, ethyl acetate, and chloroform arise because of the channel type structure of α-CD.

The precipitations of α-CD in the non-solvent system (the organic solvents) have been repeated three times to insure the production method is reproducible. The diffractograms of the α-CD crystals formed in pentane, hexane, heptane, cyclohexane, 1-butanol, 1-propanol, 1,4-dioxane, THF, ethyl acetate, and chloroform verify to the successful production of channel type α-CD crystal. The products obtained in pentane, hexane, heptane, cyclohexane, 1-butanol, 1-propanol, 1,4-dioxane, and THF contain only channel structure whereas crystals of α-CD which were obtained in ethyl acetate and chloroform consist of both cage and channel structure, especially the α-CD crystals obtained in ethyl acetate contains some cage structure.

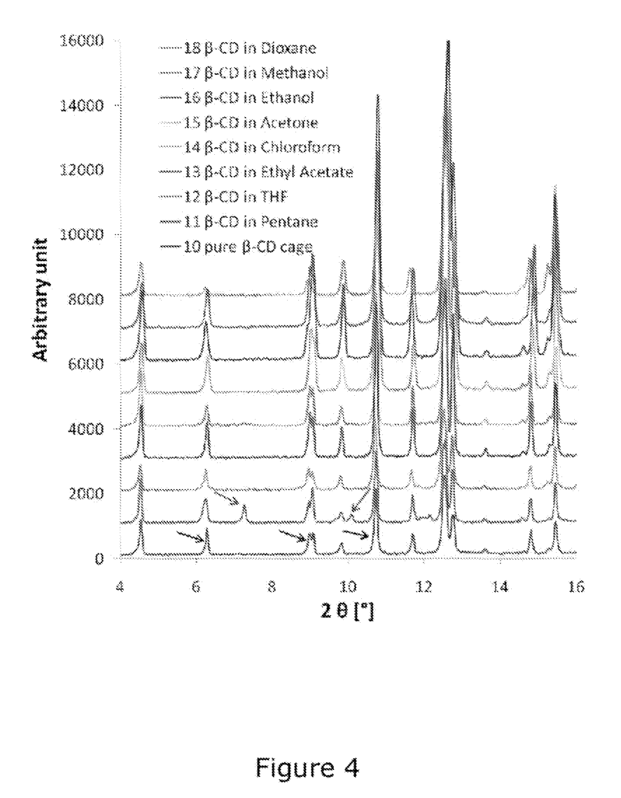

The X-ray diffractograms of the obtained β-CD crystals in different solvents (different non-solvent system) with a β-CD concentration of 35 g/L, as well as as-received β-CD are depicted in FIG. 4. The major peaks at 2θ=6.3°, 10.9° and 12.5° are shown with arrows and belong to the cage structure whereas the channel structure of β-CD have diffraction peaks located at 2θ=7.2° and 10°, also shown with arrows. The diffractograms of the products are similar to the diffractogram of cage structure in the as-received β-CD, except the β-CD crystals formed in pentane. The arrows shown for product 38 indicate channel structure but the characteristic peaks from cage type β-CD crystals are also present. After optimization, it was possible to produce pure channel structure of β-CD by precipitation in pentane. The precipitation in different solvents was performed with β-CD only once because the XRD data of the products from different solvents did not shown any significant difference compared to the diffractogram from cage type β-CD crystal.

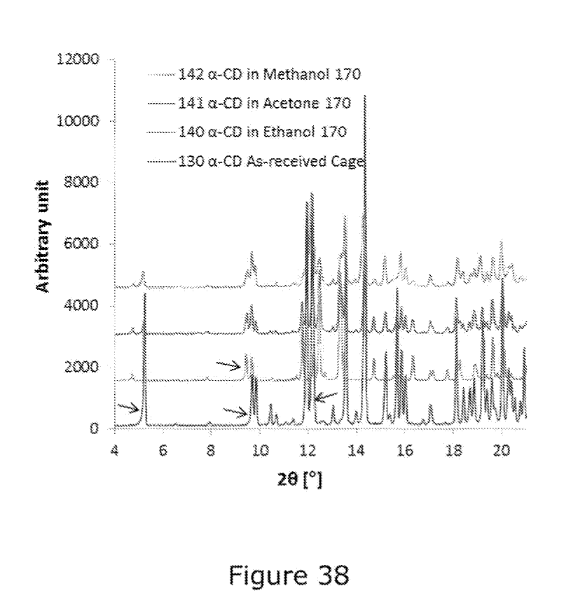

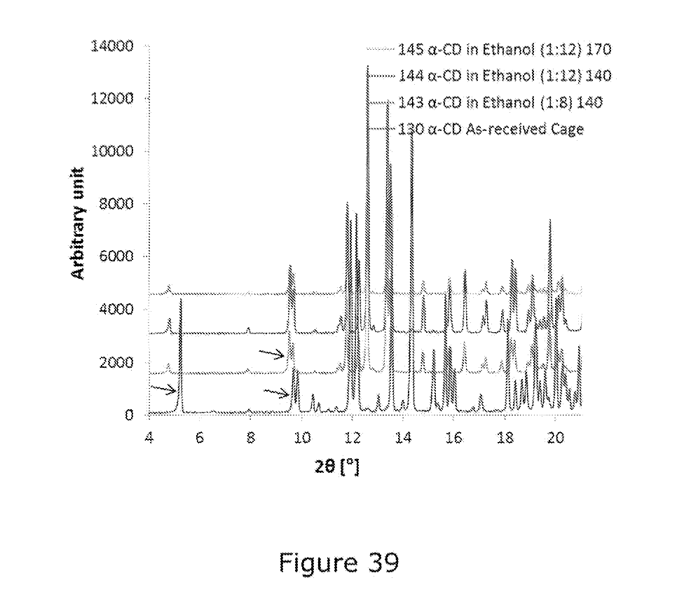

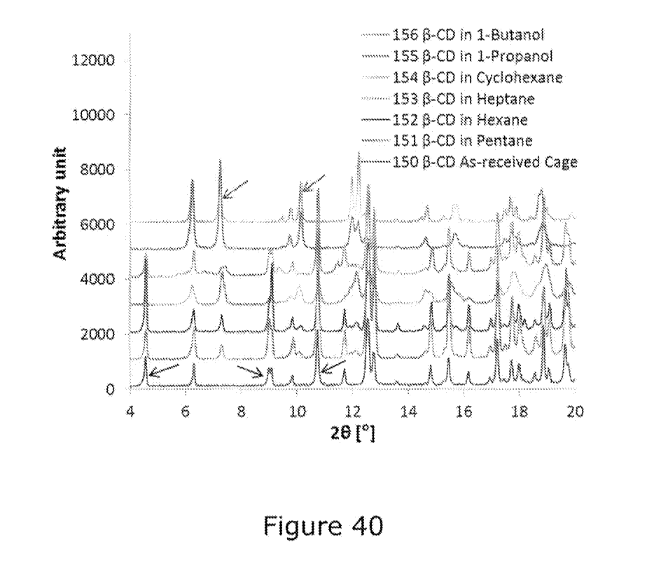

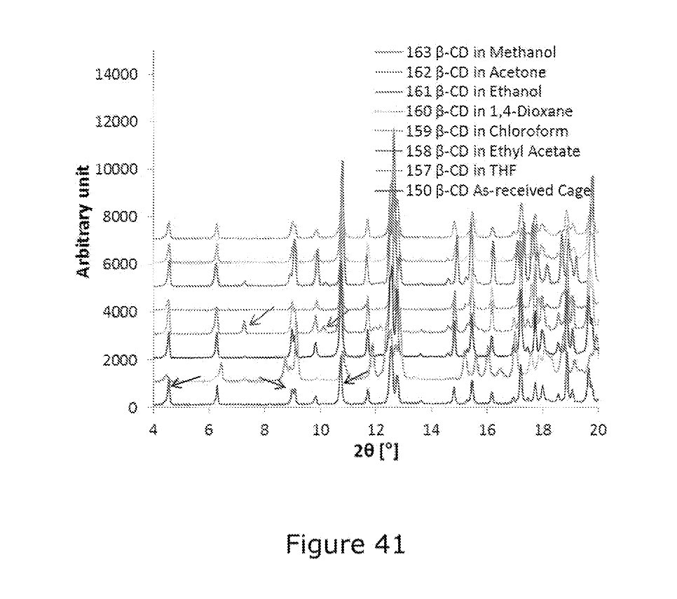

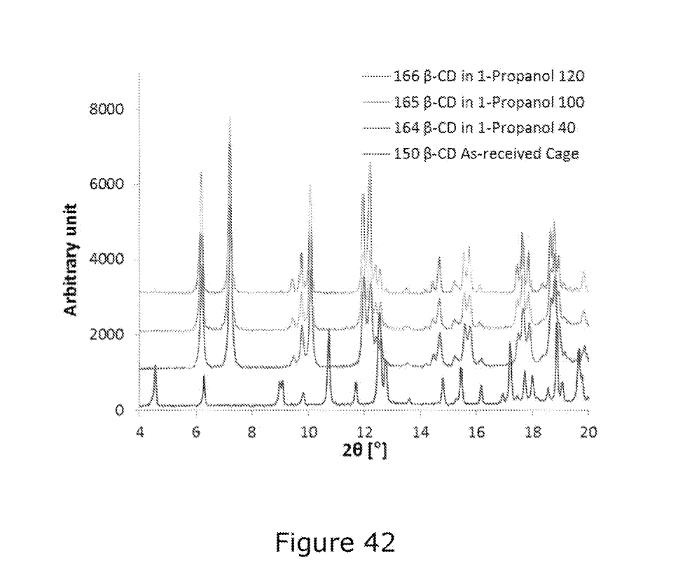

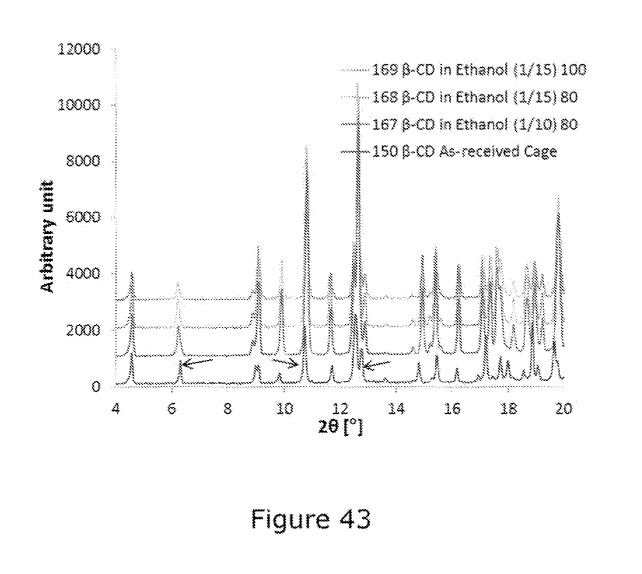

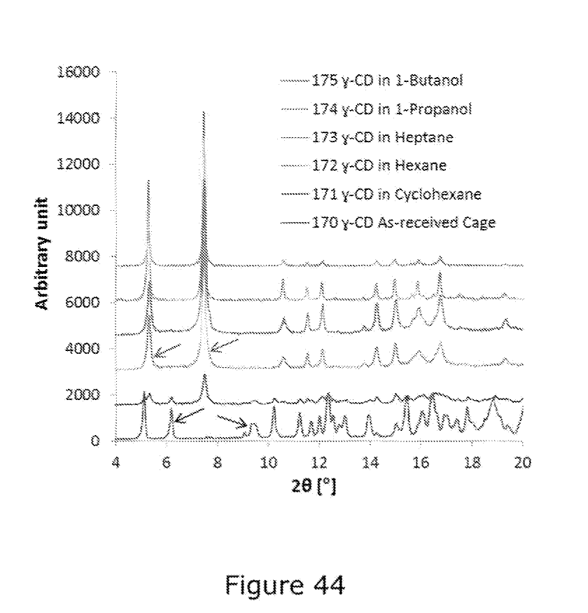

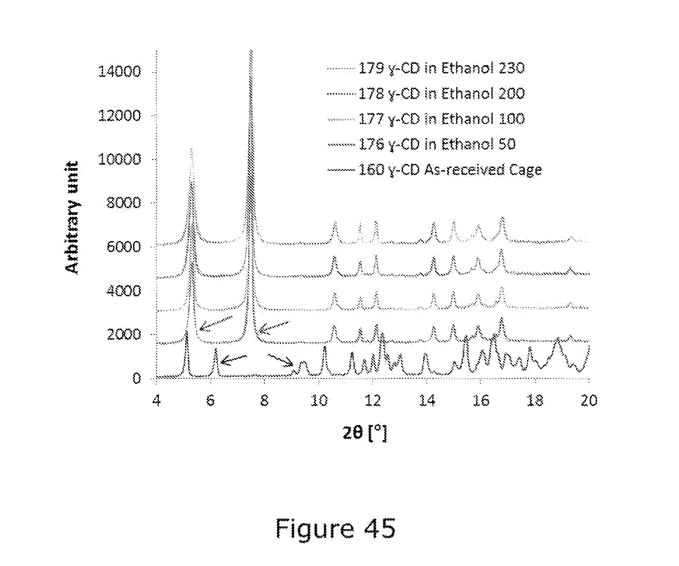

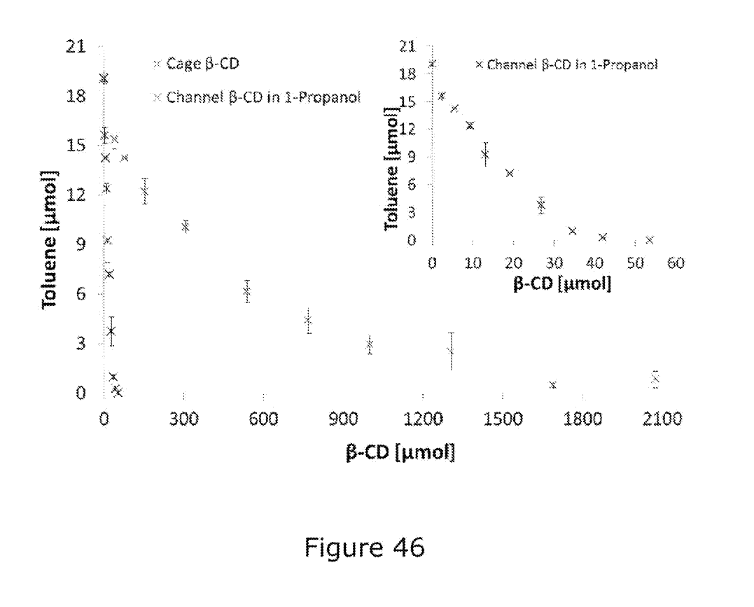

However by precipitating β-CD aqueous solution with a concentration of 80 g/L in hexane, heptane, cyclohexane, 1-butanol, and 1-propanol (non-solvent system) channel type β-CD crystal can be produced, as seen FIG. 38. Two alcohol solvents (1-propanol and 1-butanol) were the best solvents when trying to obtain channel β-CD crystal because the yield and purity of channel β-CD crystal was high and the handling was easier compared to apolar solvents.

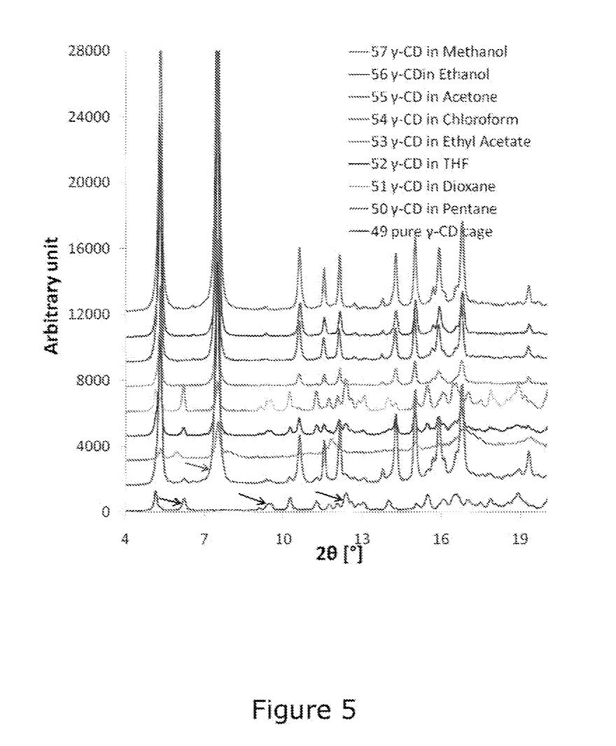

The X-ray diffractograms of γ-CD crystals formed and the as-received γ-CD crystal are depictured in the FIG. 5. The cage structured γ-CD crystal has major peaks at 2θ=6.2°, 9.5° and 12.4°, where the channel type γ-CD has peaks at 2θ=7.5°. As seen in FIG. 5, the successful production of the channel structure of γ-CD has been proven as the peak at 2θ=7.5° are found in all the γ-CD crystals obtained by precipitation in the non-solvent system (the organic solvents). The diffractograms of the γ-CD crystals produced in dioxane, chloroform, acetone, ethanol, and methanol show no peaks from cage structure. This means these crystals have minimum 95% channel structure because the detection limit of XRD equipment is 5% (65), but also depends on crystalline structures. The products obtained in pentane and THF consist mostly of channel type structure but very small peaks of cage structure at 2θ=6.2° and 9.5° indicates a small amount of the crystals has cage type structure. Product 53 obtained in ethyl acetate have both cage and channel type structure.

The degree of crystallinity of the channel structure of γ-CD can be determined based on the ratio of intensities between channel and cage type peaks, which are evaluated from the diffractograms in FIG. 5, are seen in Table 9.

TABLE 9
Int. and Int. R. is intensity and intensity ratio,
respectively. The diffractograms have been visually evaluated for
presence of channel and cage type crystal structure. Channel and cage
type crystal formation after precipitation in the shown solvent is
denoted as + and −, respectively. The brackets indicate a small
amount e.g. (−) mean a small amount of cage type crystal, and +/− is
presence of channel and cage type crystals, both in large quantities.

| | Int. at 6.2 | Int. at 7.5 | Int. R. | |
|---|---|---|---|---|
| | (cage) | (channel) | channel/cage | Structure |
| 49 received γ-CD cage | 822 | 119 | 0.14 | − |
| 50 γ-CD in Pentane | 582 | 29378 | 50.48 | +/(−) |
| 51 γ-CD in Dioxane | 320 | 2401 | 7.50 | + |
| 52 γ-CD in THF | 259 | 11463 | 44.26 | +/(−) |
| 53 γ-CD in Ethyl | 1765 | 1934 | 1.10 | +/− |
| Acetate | | | | |
| 54 γ-CD in Chloroform | 236 | 9023 | 38.23 | + |
| 55 γ-CD in Acetone | 234 | 25715 | 109.89 | + |
| 56 γ-CD in Ethanol | 197 | 17762 | 90.16 | + |
| 57 γ-CD in Methanol | 328 | 31413 | 95.77 | + |

Theoretically the intensity ratio of channel/cage structure will be lowest with 100% of the cage type crystals and highest for 100% of the channel type crystals. However the intensity ratio of the obtained γ-CD crystals from different solvents are not directly linked to the ratio between channel and cage type crystals as the baseline level also affects the signal which it is difficult to compensate for without proper software.

Product 51 contains only channel structure but the ratio is much lower compared to the channel type crystals made from pentane which has small amount of cage structure, as seen by visual interpretation of the diffractogram. The peak resolution and intensity also depends on solvent residues in a sample and particle size of powder which is affected by the packing of sample during sample preparation.

Surprisingly it was found that different solvents worked for the production of α-, β-, γ-channel type CD crystals.

Channel type α-CD crystals can be produced in pentane, hexane, heptane, cyclohexane, 1-butanol, 1-propanol, chloroform, THF, ethyl acetate, and 1,4-dioxane. Most solvents gave very pure channel type crystals as found from the diffractograms whereas ethyl acetate resulted in less pure channel type α-CD crystals.

The formation of channel type γ-CD crystals in ethanol has great industrial promise, but precipitation in ethanol is not yielding channel type crystals for α- and β-CD. The production of channel type CD crystals by precipitation in a broad range of organic solvents is successful with CD in the order γ-CD>α-CD>β-CD. The formation of channel type α-, β- and γ-CD crystals based on the precipitation method was reproducible as the deviations with triple determination were small. It is believed that channel type γ-CD crystals are easily formed because γ-CD has a more flexible structure resulting in high solubility in water compared to α- and β-CD. It gives the possibility of making high concentration γ-CD aqueous solutions which contributes to higher precipitation rate during drop wise addition to a non-solvent system (organic solvents).

It is believed that channel-type crystal nuclei are kinetically favoured over their cage type counterparts. This is expected to be because the channel type dimers, trimmers, and so on have more hydrogen bonds per CD than the cage-type, meaning a lower energy barrier for nucleation. This is also expected to be why the precipitate must be filtrated immediately to achieve a channel type structure, as the dissolution and rearrangement of crystals (from channel to cage structure) occurs until the solvent is removed, and rearrangement to the thermodynamically stable cage-structure therefore not arrested. A reason which can explain the difficulty in producing channel type α- and β-CD crystals is that the channel type crystals are metastable crystals. The transformation of the metastable phase (channel structure) to the stable phase (cage structure) requires activation energy. For the channel type β-CD crystals, the activation energy required might be very small, therefore the channel structure of β-CD in metastable phase will easier end in the ultimately stable crystal phase (cage structure). The activation energy required to transform from metastable phase to stable phase of α-CD may be higher than β-CD which explains the increased stability as well as the increased number of solvents that yield α-CD channel crystals. The rigid structure of β-CD is influence the formation of channel structure of β-CD; it might demand more energy to organize molecules into channel structure, compared to α- and γ-CD.

A summary of the most important experiments can be found in the below tables 10-13; P′ is the Snyder polarity index; ‘−’ indicates the formation of cage type CD, and ‘+’ indicates the formation of channel type crystal; the brackets indicate a small amount, e.g. ‘(+)’ mean a small amount of channel type crystal.

TABLE 10
The aqueous α-CD solutions in different
concentrations were precipitated in the organic solvents. Each product
has a own number. Number in the bracket is product number. Channel
and cage type crystal formation after precipitation in the shown solvent
is denoted as + and −, respectively. The brackets indicate a small
amount e.g. (−) mean a small amount of cage type crystal, and +/− is
presence of channel and cage type crystals, both in large quantities.

| | Concentration of α- | | |
|---|---|---|---|
| Product nr. | CD solution [g/L] | Precipitation in Solvents | Structure |
| 2, 45, 70 | 140 | Methanol (P′ = 6.6) | − |
| 4, 38, 64, 71 | 140 | Pentane (P′ = 0.0) | + |
| 5, 40, 65 | 140 | THF (P′ = 4.2) | +; +; +/(−) |
| 6, 41, 66 | 140 | Ethyl acetate (P′ = 4.4) | +/− |
| 42, 67 | 140 | Chloroform (P′ = 4.1) | + |
| 8, 43, 68 | 140 | Acetone (P′ = 5.4) | − |
| 9, 44, 69 | 140 | Ethanol (P′ = 5.2) | − |
| 25, 39 | 140 | 1,4-Dioxane (P′ = 4.8) | + |
| 83 | 140 | Pentane: 70° C./RT | + |
| 84 | 140 | Pentane: RT/RT | + |
| 85 | 140 | THF: 70° C./RT | + |
| 86 | 140 | THF: RT/RT | + |
| 131 | 140 | Cyclohexane (P′ = 0.0) | + |
| 132 | 140 | Hexane (P′ = 0.0) | + |
| 133 | 140 | Heptane (P′ = 0.0) | + |
| 134 | 140 | 1-Propanol (P′ = 3.9) | + |
| 135 | 140 | 1-Butanol (P′ = 4.0) | + |
| 136 | 50 | Pentane (P′ = 0.0) | +/(−) |
| 137 | 80 | Pentane (P′ = 0.0) | + |
| 138 | 170 | Pentane (P′ = 0.0) | +/(−) |
| 139 | 190 | Pentane (P′ = 0.0) | +/(−) |

TABLE 11
The aqueous β-CD solutions in different
concentrations were precipitated in the organic solvents. Each product
has an own number. Number in the bracket is product number. Channel
and cage type crystal formation after precipitation in the shown solvent
is denoted as + and −, respectively. The brackets indicate a small
amount e.g. (−) mean a small amount of cage type crystal, and +/− is
presence of channel and cage type crystals, both in large quantities.

| Product | Concentration of β- | | |
|---|---|---|---|
| nr. | CD solution [g/L] | Precipitation in Solvents | Structure |
| 11 | 35 | Pentane (P′ = 0.0) | +/− |
| 12 | 35 | THF (P′ = 4.2) | − |
| 13 | 35 | Ethyl acetate (P′ = 4.4) | − |
| 14 | 35 | Chloroform (P′ = 4.1) | − |
| 15 | 35 | Acetone (P′ = 5.4) | − |
| 16 | 35 | Ethanol (P′ = 5.2) | − |
| 17 | 35 | Methanol (P′ = 6.6) | − |
| 18 | 35 | 1,4-Dioxane (P′ = 4.8) | − |
| 141 | 80 | Pentane (P′ = 0.0) | +/− |
| 142 | 80 | Hexane (P′ = 0.0) | +/− |
| 143 | 80 | Heptane (P′ = 0.0) | + |
| 144 | 80 | Cyclohexane (P′ = 0.0) | +/− |
| 145 | 80 | 1-Propanol (P′ = 3.9) | + |
| 146 | 80 | 1-Butanol (P′ = 4.0) | + |
| 147 | 80 | THF (P′ = 4.2) | − |
| 148 | 80 | Ethyl Acetate (P′ = 4.4) | − |
| 149 | 80 | Chloroform (P′ = 4.1) | (+)/− |
| 150 | 80 | 1,4-Dioxane (P′ = 4.8) | − |
| 151 | 80 | Ethanol (P′ = 5.2) | (+)/− |
| 152 | 80 | Acetone (P′ = 5.4) | − |
| 153 | 80 | Methanol (5.4) | − |
| 154 | 18 | 1-Propanol (P′ = 3.9) | No product |
| 155 | 40 | 1-Propanol (P′ = 3.9) | + |
| 156 | 100 | 1-Propanol (P′ = 3.9) | + |
| 157 | 120 | 1-Propanol (P′ = 3.9) | + |

TABLE 12
The aqueous γ-CD solutions in different
concentrations were precipitated in the organic solvents. Each product
has a own number. Number in the bracket is product number. Channel
and cage type crystal formation after precipitation in the shown solvent
is denoted as + and −, respectively. The brackets indicate a small
amount e.g. (−) mean a small amount of cage type crystal, and +/− is
presence of channel and cage type crystals, both in large quantities.

| Product | Concentration of γ- | | |
|---|---|---|---|
| nr. | CD solution [g/L] | Precipitation in Solvents | Structure |
| 19, 52, 72 | 180 | THF (P′= 4.2) | +; +; +/(−) |
| 20, 53, 73 | 180 | Ethyl acetate (P′= 4.3) | +/− |
| 21, 54, 74 | 180 | Chloroform (P′= 4.1) | +/−; +; +/− |
| 55, 75 | 180 | Acetone (P′= 5.4) | + |
| 56, 76 | 180 | Ethanol (P′= 5.2) | + |
| 77 | 180 | Methanol (P′= 6.6) | + |
| 29, 50 | 180 | Pentane (P′= 0.0) | + |
| 34, 51 | 180 | 1,4-Dioxane (P′= 4.8) + | |
| 87 | 180 | Pentane: 70° C./RT | + |
| 88 | 180 | Pentane: RT/RT | + |
| 89 | 180 | THF: 70° C./RT | + |
| 90 | 180 | THF: RT/RT | + |
| 91 | 180 | Acetone: 70° C./RT | + |
| 92 | 180 | Acetone: RT/RT | + |
| 93 | 180 | Ethanol: 70° C./RT | + |
| 94 | 180 | Ethanol: RT/RT | + |
| 161 | 180 | Hexane (P′= 0.0) | + |
| 162 | 180 | Heptane (P′= 0.0) | + |
| 163 | 180 | Cyclohexane (P′= 0.0) | + |
| 164 | 180 | 1-Propanol (P′= 3.9) | + |
| 165 | 180 | 1-Butanol (P′= 4.0) | + |
| 166 | 50 | Ethanol (P′= 5.2) | + |
| 167 | 100 | Ethanol (P′= 5.2) | + |
| 168 | 200 | Ethanol (P′= 5.2) | + |
| 169 | 230 | Ethanol (P′= 5.2) | + |

TABLE 13
Overview of the result of channel CD production
in organic solvents. Channel and cage type crystal formation after
precipitation in the shown solvent is denoted as + and −, respectively.
The brackets indicate a small amount e.g. (−) mean a small amount of
cage type crystal, and +/− is presence of channel and cage type
crystals, both in large quantities.

| | | | | | γ-CD |
|---|---|---|---|---|---|
| Precipitation | Polarity | Relative | α-CD | β-CD | [180 |
| in Solvents | Index | polarity | [140 g/L] | [80 g/L] | g/L] |
| Pentane | 0 | 0.009 | + | +/− | + |
| Hexane | 0 | 0.009 | + | +/− | + |
| Heptane | 0 | 0.012 | + | + | + |
| Cyclohexane | 0 | 0.006 | + | +/− | + |
| 1-butanol | 3.9 | 0.586 | + | + | + |
| 1-propanol | 4 | 0.617 | + | + | + |
| Chloroform | 4.1 | 0.259 | + | (+)/− | + |
| THF | 4.2 | 0.207 | + | − | + |
| Ethyl | 4.3 | 0.228 | +/− | − | +/(−) |
| acetate | | | | | |
| 1,4-Dioxane | 4.8 | 0.164 | + | − | + |
| Ethanol | 5.2 | 0.654 | − | (+)/− | + |
| Acetone | 5.4 | 0.355 | − | − | + |
| Methanol | 6.6 | 0.762 | − | − | + |

As can be deducted from the tables, when the cyclodextrin is a α-cyclodextrin, the non-solvent system must preferably have a Snyder polarity index (P′) of less than about 5 when single solvents (non-mixtures) are used. Higher values of P′ may be used for mixtures. When the cyclodextrin is a β-cyclodextrin, the non-solvent system must preferably have a Snyder polarity index (P′) of less than 4 when single solvents (non-mixtures) are used. Higher values of P′ may be used for mixtures, and ethanol also yields some channel type crystals. When the cyclodextrin is a γ-cyclodextrin, the non-solvent system seems not to be limited to a specific value of the Snyder polarity index (P′). One apparent limitation for the production of α-, β-, γ-channel type CD crystals is that the non-solvent system, when soluble in water, must have a viscosity suitable for separating the α-, β-, or γ-channel type CD crystals from the non-solvent system. This was difficult when the non-solvent system was tetraglycol or 1,2-propanediol, both having a dynamic viscosity above 50 cP (centipoise) at room temperature (20-25 degrees Celsius).

The yield of channel type CD production by precipitation method is usually very high, as shown in Table 14. Especially the production of channel type CD crystals in polar protic solvent such as 1-propanol, 1-butanol, and ethanol gained a highest yield compared to in polar aprotic and apolar solvent. The production yield in organic solvent is in the order (highest to lowest yield) polar aprotic>polar aprotic>apolar solvent. The yield also depends on concentration of CD aqueous solution used during production. The higher CD concentration used the high yield obtained in the same solvent.

TABLE 14
The yield of channel type α-, β-, and γ-CD crystals
obtained by precipitation method in different solvents where
polar protic (1-propanol, 1-butanol, and ethanol), polar aprotic
(acetone), and apolar solvent (pentane, hexane, and heptane). Cage
and channel structure is denoted as − and +, respectively.

| | | Concentration | Precipitation | | Yield |
|---|---|---|---|---|---|
| Product nr. | CD | [g/L] | in | Structure | [%] |
| 11 | α-CD | 50 | Pentane | +/(−) | 53 |
| 12 | α-CD | 170 | Pentane | +/(−) | 72 |
| 3 | β-CD | 80 | Pentane | +/− | 77 |
| 4 | β-CD | 80 | Hexane | +/− | 71 |
| 5 | β-CD | 80 | Heptane | +/− | 79 |
| 7 | β-CD | 80 | 1-Propanol | + | 81 |
| 8 | β-CD | 80 | 1-Butanol | + | 84 |
| 24 | γ-CD | 180 | Ethanol | + | 94 |
| 25 | γ-CD | 180 | Acetone | + | 93 |
| 26 | γ-CD | 180 | Pentane | + | 82 |

### Example 8

### Investigation of the Influence of Temperature on the Crystal Structure

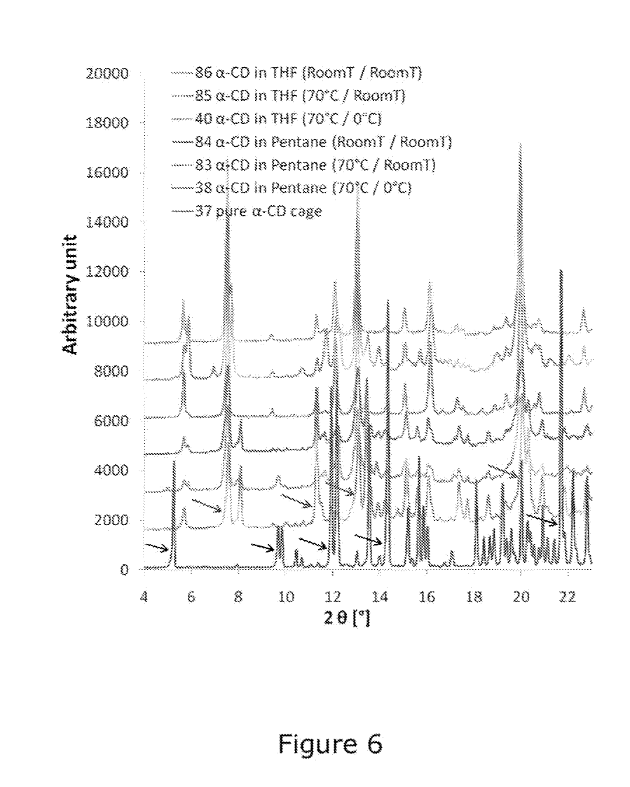

The diffractograms of the products obtained by precipitating α-CD solution in pentane and THF at different temperatures are shown in FIG. 6. Product 38, 40, 83 and 85 were obtained by precipitating a 70° C. α-CD solution into the non-solvent system (pentane or THF) at 0° C. and room temperature, respectively, where product 84 and 86 was obtained in the same way but both CD solution and the solvents were kept at room temperature. Precipitation at different temperature results in cooling rates in the order of: CD solution at 70° C./0° C.>70° C./room temperature solvent>room temperature/room temperature solvent. In FIG. 6, the diffractograms of the products containing channel type peaks, seen at 2θ=5.7°, 7.6°, 11.3°, 13.1°, and 20°, are shown with arrows. This means that different cooling rates have no significant influence on the formation of channel type CD crystals.

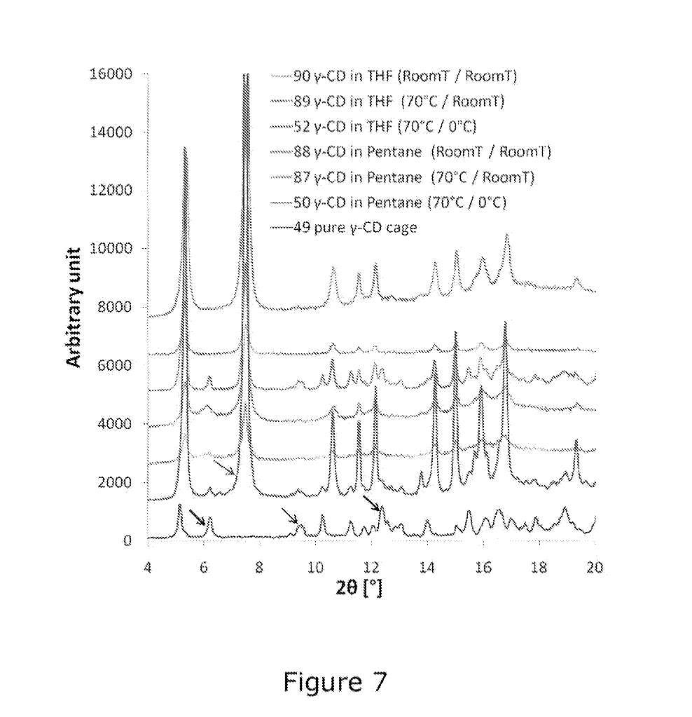

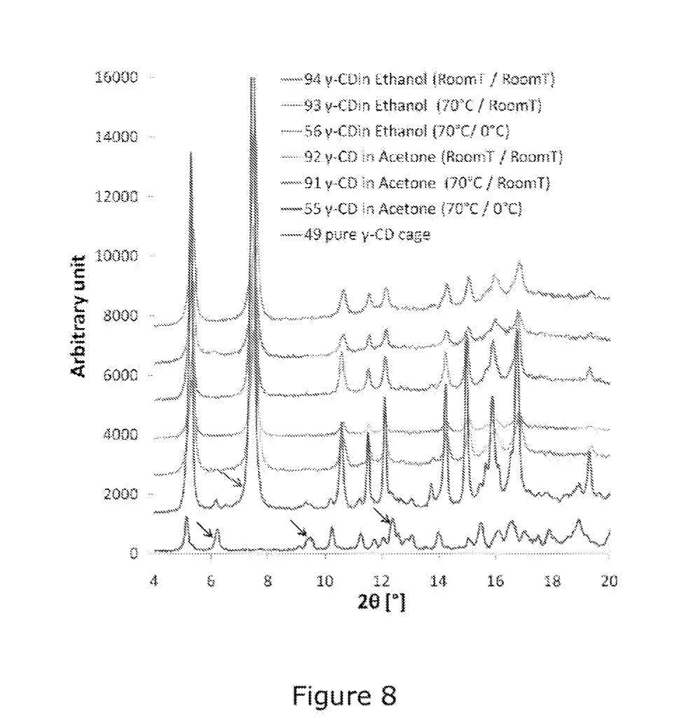

X-ray diffractograms of the γ-CD products obtained after precipitation in pentane, THF, acetone, and ethanol at different temperatures are shown in FIG. 7 and FIG. 8. As described earlier, the cage and channel structured γ-CD crystals have major peaks at 2θ=6.2° and 9.5° and at 2θ=7.5°, respectively. The diffractograms show the presence of channel peaks at 2θ=7.5° in all products.

In FIG. 7, products 50 and 52 obtained by the highest cooling rate (CD solution at 70° was drop wise added into ice-cold solvent) contain a small amount of cage structure at 2θ=6.2°. The diffractograms of product 87 and 88 obtained in pentane also have a small cage peak at 2θ=6.2° where product 89 and 90 made under the same condition but in THF, contain only channel type γ-CD crystals. The channel type γ-CD crystals were easier to obtain in THF at room temperature than in pentane.

The diffractogram of product 55 obtained in acetone has a small cage peak at 2θ=6.2° where the remaining products, contain channel type γ-CD crystals; especially the product from precipitation in ethanol, as shown in FIG. 8. Ethanol is the best of the four solvents tested to produce channel type γ-CD, at the same time ethanol is a non-toxic solvent and used for many industrial purposes. It is also an advantage to produce CD channel crystals at room temperature therefore the production of channel type γ-CD crystals in room temperature ethanol will give a huge economic advantage compared to the other production methods.

The production of channel type CD crystal does not seem to be affected by the different temperatures of CD solution and solvents (different cooling rates). The production of channel type crystals is uncomplicated and easily produced because no significant temperature control is needed in the precipitation process, therefore the solvent is the most important parameter for the formation of channel type CD. In order to investigate if more extreme cooling rates influence the precipitation without use of solvent, the experiments in next section was carried out.

### Example 9

### The Precipitates Obtained by Cooling Aqueous CD and CD with Channel Type Seeds Solution in Nitrogen, Ice-Bath, and Room Temperature

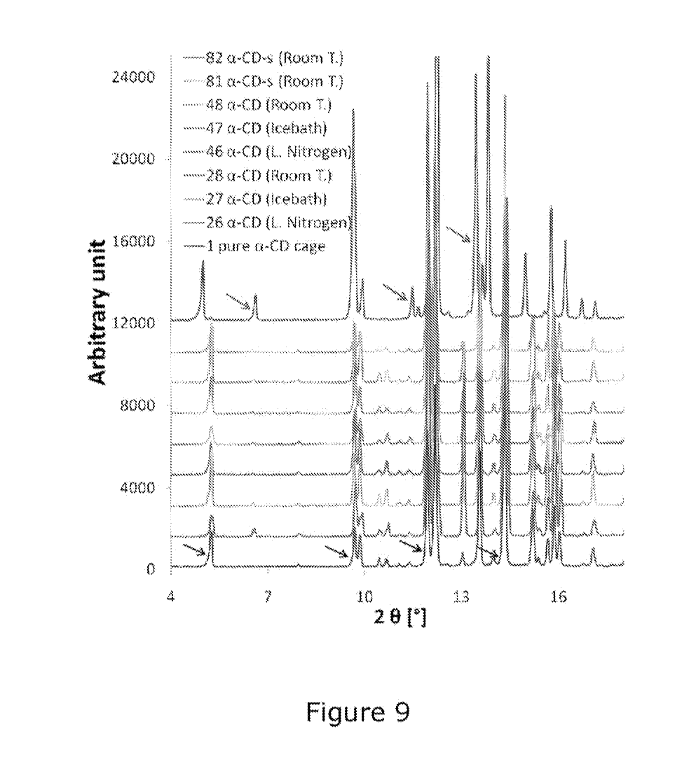

The diffractograms of α-CD products obtained by quick cooling of oversaturated 50° C. α-CD solution and α-CD solution with channel crystals seeded in solution, in liquid nitrogen, ice-bath, and room temperature are shown in FIG. 9. The diffractograms of all the α-CD products have cage peaks at 2θ=5.3°, 9.7°, 9.8°, 12°, 12.3°, and 14.4° except product 82 which also has channel peaks at 2θ=7.6°, 11.3° and 13.1°. The difference between product 82 and the other products is that the α-CD concentration is the highest at 500 g/L where the solubility of α-CD at room temperature is 145 g/L and product 81 has the next highest concentration of α-CD. Both products were obtained by seeded crystallization, and the weight ratio of CD and seed crystals (channel crystals from product 40) is 1:0.01 and 1:0.05 for product 81 and 82, respectively.

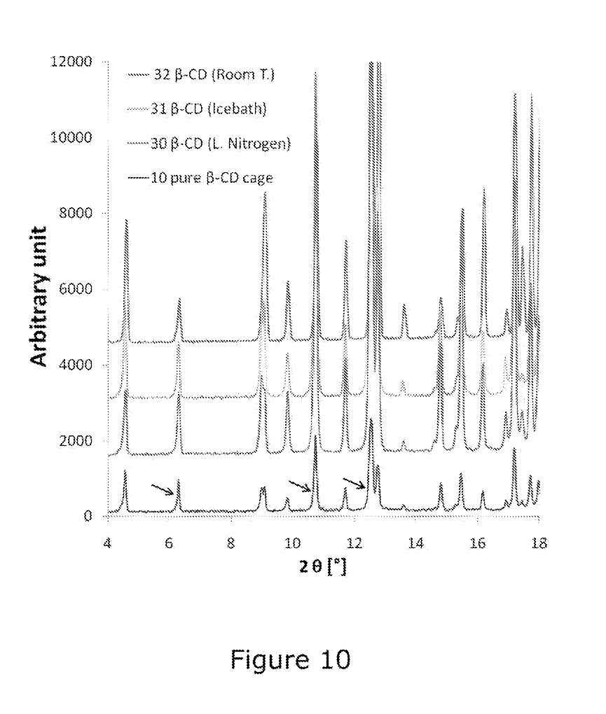

The X-ray diffractograms of the β-CD crystals obtained by cooling in liquid nitrogen, ice-bath, and room temperature are shown in FIG. 10. Their diffractograms are completely similar to as-received β-CD's diffractogram. All the diffractograms have major cage peaks at 2θ=6.3°, 10.9° and 12.5° which are shown with arrows, where the products have more distinct peaks compared to the as-received β-CD. It means that the cage type β-CD crystals of the products are more pure and more ordered than as-received β-CD. The formation of channel type β-CD was not reached since β-CD molecules were previously studied by Rao et al. (66) and it was found that β-CD molecules self-aggregated in water. The self-aggregation may result in nuclei with cage structure and then grow to β-CD crystals. Only product 30 showed precipitates during cooling where the other precipitates were collected after one day. However, result from product 30 is similar to product 31 and 32.

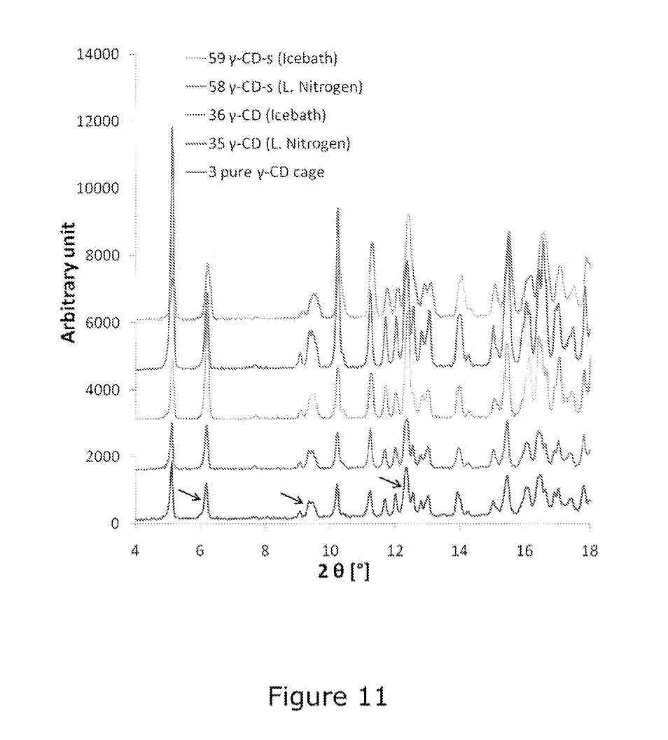

The diffractograms of product 35, 36, 58 and 59 obtained from γ-CD and the as-received γ-CD crystals are depictured in FIG. 11. The peaks of cage structured γ-CD crystal at 2θ=6.2°, 9.5° and 12.4° (shown with arrows) are present in all the products. No channel peak at 2θ=7.5° can be seen although a small amount of channel crystals was expected in product 58 and 59 because they were seeded with channel crystals before cooling. The crystal growth happen on already formed channel crystal and thereby gives a product with channel type crystals.

In conclusion, the production of channel type CD crystal by quick cooling of aqueous CD solution with and without seeding was unsuccessful. Maybe the production method used was suitable for water medium or channel CD particles used for seeding were not small enough to initiate nucleation for the growth of channel type CD crystals. Therefore, the cooling rate is not a great factor in the formation of channel type CD crystals in water solution but the solvent is the most important factor for producing channel type CD crystals

Calculation of Water and Solvent Residues in the Channel Type CD by use of 1H NMR

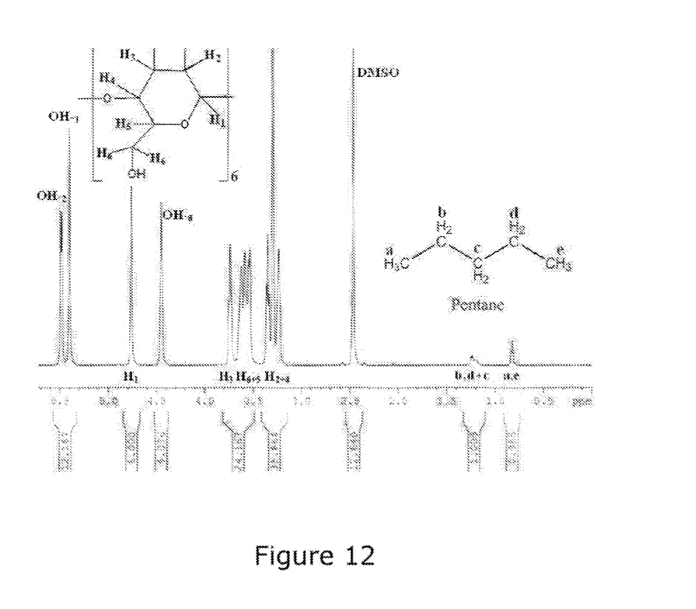

The 1D ¹H NMR spectrum of product 38 produced in pentane is shown in FIG. 12 as a representative sample of the measured products, where the different proton signals are the basis for the calculation of the solvent/water content in relation to the CD.

The proton has the most deshielded peak at 5 ppm due to the two ether bonds, one from the D-glucopyranose unit and one from the oxygen bridge-binding between two D-glucopyranose units. The chemical shifts of the other protons are in the order H3>H6>H5>H2>H4 with the peaks of H6 and H5 overlapping a little. The protons of pentane are most shielded because they belong to methyl and ethylene groups.

The area of H1 and solvent protons from the 1H NMR spectrum were used to determine the molar ratio of solvent:CD. Afterwards the amount of water and solvent residue in CD channel type crystals were calculated using the data from TGA measurements. The equation used for calculation of the molar ratio of solvent and CD is shown in Equation 1 below,

$$Molar ratio = \frac{{n}_{s}}{{n}_{CD}} = \frac{\frac{{A}_{HS}}{{H}_{s}}}{\frac{{A}_{H 1}}{{H}_{{1}_{CD}}}}$$

where nₛ and n_{CD} are the number of moles of solvent and CD, respectively. A_{HS} is the area of all protons from the solvent and A_{H1} is the area of H1 from CD. HS and H1_{CD} are total protons of one solvent and total H1 of one CD molecule. For instance, α-CD has a total of six H1 where γ-CD has a total of eight.

An example of how molar ratio of α-CD:pentane is calculated from areas shown in FIG. 12, is shown below:

$$Molar ratio = \frac{\frac{( 1.005 + 0.985 )}{( 3 + 2 + 2 + 2 + 3 )}}{\frac{6}{6}} = 0.17$$

The calculated molar ratio and the mass percent between CD, solvent, and water are shown in Table 15. A corresponding calculation has been performed on γ-CD as shown in Table 16.

TABLE 15
The amount of water and solvent residue contained in α-CD
channel type crystals produced from different solvents. The results
are shown as both molar relationship and a mass percentage.

| | | Water:α- | Solvent:α- | | | |
|---|---|---|---|---|---|---|
| | Prod- | CD | CD | Mass α- | Mass | Mass |
| | uct | [mol/1 | [mol/1 | CD | Water | Solvent |
| Solvent | nr. | mol] | mol] | [%] | [%] | [%] |
| Pentane | 38 | 4.65 | 0.17 | 91.04 | 7.83 | 1.12 |
| Dioxane | 25 | 1.04 | 2.09 | 82.7 | 1.6 | 15.7 |
| THF | 40 | 1.31 | 1.02 | 90.91 | 2.21 | 6.88 |
| Ethyl | 41 | 3.33 | 0.7 | 88.9 | 5.49 | 5.61 |
| Acetate | | | | | | |
| Chloroform | 42 | 4.42 | 0.28 | 89.62 | 7.34 | 3.04 |

TABLE 16
The amount of water and solvent residue contained in γ-CD
channel type crystals produced from different solvents. The results
are shown as both molar relationship and a mass percentage.

| | | Water:γ- | Solvent:γ- | | | |
|---|---|---|---|---|---|---|
| | Prod- | CD | CD | Mass γ- | Mass | Mass |
| | uct | [mol/1 | [mol/1 | CD | Water | Solvent |
| Solvent | nr. | mol] | mol] | [%] | [%] | [%] |
| Pentane | 50 | 7.59 | 0.18 | 86.93 | 12.21 | 0.86 |
| Dioxane | 34 | 6.09 | 2.24 | 79.03 | 8.91 | 12.05 |
| THF | 52 | 4.75 | 0.27 | 90.68 | 7.97 | 1.35 |
| Ethyl | 53 | 5.29 | 0.07 | 90.66 | 8.88 | 0.46 |
| Acetate | | | | | | |
| Chloroform | 54 | 12 | 0.16 | 80.85 | 17.97 | 1.18 |
| Acetone | 55 | 8.29 | 0.2 | 86.04 | 13.21 | 0.76 |
| Ethanol | 56 | 8.3 | 0.07 | 86.49 | 13.29 | 0.22 |
| Methanol | 57 | 6.16 | 1.58 | 86.72 | 9.89 | 3.39 |

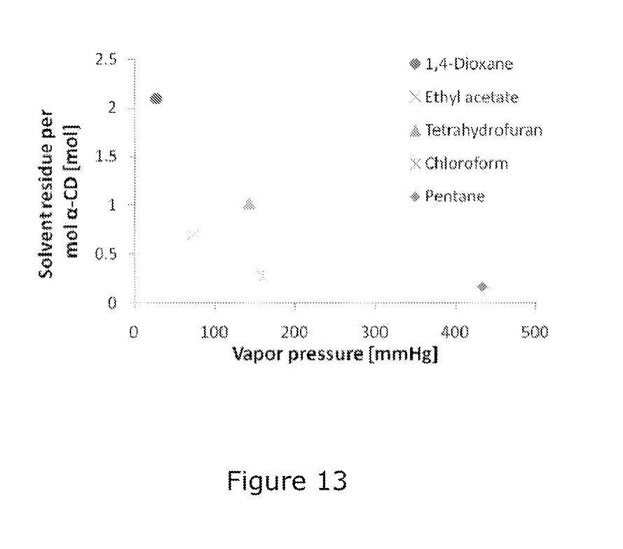

The mass percent of α-CD for channel type crystals obtained in pentane (product 38) and dioxane (product 39) is highest (91.04%), and lowest (82.70%), respectively. The mass percent of water is also highest for product 38 and least for product 25. Product 42 contains a lot of water compared to product 40 and 41. The molar ratio of water:α-CD of the products in order from high to low: product 38, 42, 41, 40, and 25 which correspond to solubility of the solvent in water in the reversed order (low to high): pentane, chloroform, ethyl acetate, THF, and dioxane. In order to form and stabilize channel type CD crystals, the presence of hydrogen bonding appears to be necessary. Hydrogen bonding between CD and water, or CD and solvent which have at least one electronegative atom is a requirement for the formation of a crystal form. In this case, pentane cannot form hydrogen bonding with the hydroxyl group of CD. Therefore, more water is required to form and stabilize channel type crystals γ-CD. The molar ratio of α-CD:solvent for the products is the reversed order of the water content (low to high): product 38, 42, 41, 40, and 25. The phenomena can be explained with higher vapor pressure the solvents are evaporated during drying. Product 38 contains the least solvent because the vapor pressure of pentane is higher than the other solvents, as can be seen in Table 4 and the correlation between solvent content and vapor pressure is apparent, as seen FIG. 13. At the same time some solvents are not needed for stabilizing the CD and therefore the content is lower. Dioxane has lowest vapor pressure and product 25 has the most solvent residue in α-CD channel crystals. Product 40 produced in THF contains more solvent residue than product 41 produced in ethyl acetate, although the vapor pressure of THF is higher than ethyl acetate. This is because THF is soluble in water and ethyl acetate is not which results in THF interacting with the CD during precipitation instead of doing phase separation as the ethyl acetate.

The channel type γ-CD crystals from eight products: 34, 50, 52-57 produced in different organic solvents, were measured by ¹H NMR. The molar ratio of water:γ-CD and solvent:γ-CD as well as their mass percent can also be seen in Table 16.

In Table 16, the γ-CD mass percent of product 52 is highest where product 34 has the lowest mass percentage of γ-CD. Mass percent of product 53 is very close to product 52. The remaining products have a mass percent from 80% to 87%. The molar ratio of water:γ-CD of the products are in the order, from high to low: product 54, 56, 55, 50, 57, 34, 53 and 52. The water:γ-CD molar ratio is not in accordance with the solvent solubility like water:α-CD. The γ-CD channel crystals produced in an apolar solvent such as pentane or chloroform contain the most water. Product 50, produced in pentane, has fourth most water where product 54, produced in chloroform, contains the most water. Water contained in channel type CD crystals is not a problem if the water can stabilize channel structure because water in the final product causes no process or health issues. However, some solvents like chloroform, dioxane etc. is harmful and unsafe for human consumption. Therefore, the amount of the harmful solvents in channel type CD crystal has to be minimized.

The products containing the least amount of solvent is in order from low to high: product 56, 53, 54, 50, 55, 52, 57 and 34 (in solvent order: ethanol, ethyl acetate, chloroform, pentane, acetone, THF, methanol, and 1,4-dioxane) where the vapor pressure of the solvent is in order from high to low: pentane, acetone, chloroform, THF, methanol, ethyl acetate, ethanol, and 1,4-dioxane, as can be seen in Table 4. Only product 34 produced in 1,4-dioxane has a solvent amount expected from its vapor pressure. Product 57 obtained in methanol contains a lot of solvent, 1.58 mol methanol for each mol of γ-CD channel crystals which is very high compared to the remaining products. Ethyl acetate residue in product 53 is very small but the product contains both cage and channel type crystals. Therefore the ethyl acetate is not a suitable solvent for the production of CD channel crystals despite the low solvent content. The product produced in dioxane contains the most solvent residue and 1,4-dioxane is a toxic solvent, for that reason 1,4-dioxane is not a suitable solvent for CD channel crystals production either. The best product is product 56, produced in ethanol, with only 0.07 mol ethanol for each mol channel type γ-CD crystal, while the solvent is un-harmful. Ethanol results in channel type crystals and is non-toxic solvent. Hence, the ethanol residue in CD channel crystals gives no problems in the process or final product.

After channel type CD crystal production, the solvent content in the products were measured by use H NMR. The solvent residue in the products depended on how long the drying process occurred. All the obtained products were dried overnight in a fume hood at room temperature. The calculated molar ratio between solvent and channel type α-, β-, and γ-CD are shown in Table 17.

TABLE 17
The amount solvent residue contained in
channel type crystals α-, β-, and γ-CD produced in organic solvent in
new experiment. The results are shown molar ratio between molar
solvent and 1 mol of CD.

| | Vapor | Mol Ratio | Mol Ratio | Mol Ratio | |
|---|---|---|---|---|---|
| | pressure | Solvent: | Solvent: | Solvent: | Product nr. |
| | at | α-CD | β-CD | γ-CD | of |
| | 25° C. | [mol/ | [mol/ | [mol/ | (α-, β-, |
| Solvent | [mmHg] | 1 mol] | 1 mol] | 1 mol] | γ-CD) |
| Pentane | 512.25 | 0.166 | 0.046 | 0.178 | 38, 151, 50 |
| Hexane | 166.5 | 0.358 | 0.061 | 0.598 | 132, 152, 172 |
| Heptane | 45.675 | 0.371 | 0.354 | 1.032 | 133, 153, 173 |
| Cyclohexane | 97.5 | 0.486 | 0.282 | 0.349 | 131, 154, 171 |
| 1-butanol | 6.45 | 0.846 | 1.016 | 1.638 | 135, 156, 175 |
| 1-propanol | 20.7 | 0.786 | 0.749 | 0.909 | 134, 155, 174 |

As mentioned the solvent residue in a product containing channel type CD crystal depends on vapour pressure of this solvent. It is explained why products making in 1-butanol and 1-propanol contain more solvent compared to the rest of the solvents.

### Example 10

### Investigating Properties and Selectivity of Cage and Channel Type CD Crystals in Gas Phase

The absorption (or adsorption if the CD cavity is seen as a surface area) ability of channel type CD crystals of gas phase guests has been studied. Gas chromatography (GC) was used to investigate the absorption ability and selectivity of both cage- and channel structured CD. Five volatile model guests was used; an aromatic hydrocarbon (Toluene), a monocyclic monoterpene (D-Limonene), a linear terpene (β-Myrcene), an ester (Methyl Acetate), and a primary alcohol (1-Butanol) (Their structures are shown below).

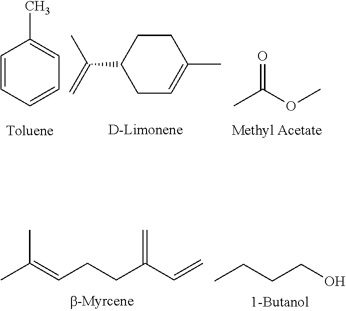

All the guest molecules should be in the gas-phase i.e. the amount of guest used has to be under the saturated gas phase pressure when used in the experiments. Calculation on the amount of guest used is principally based on the ideal gas law, as seen in Equation 2 and Equation 3;

PV=nRT Equation 2

m=M_{w}*n Equation 3

where P is the absolute pressure of the guest in gas phase, V is the volume, n is the number of moles of guest in gas phase, R is the ideal gas constant, T is the absolute temperature, m is mass, and Mw is molecular weight of the guest. In this case, P and R can be found in literature, where T and V are the temperature and volume of the gas in the experiment which can be chosen. An example of how the amount of toluene in saturated gas phase calculated is shown below.

$$PV = nRT ↔ n = \frac{PV}{RT} \to n = \frac{26 mmHg * 0.02 L}{62.36 {LmmHgK}^{- 1} {mol}^{- 1} * 298.3 K} = 2.8 {10}^{- 5} mol$$

$$m = {M}_{w} * m ↔ {V}_{1} D = {M}_{w} * n ↔ {V}_{1} = \frac{{M}_{w} * n}{D} = \frac{92.14 \frac{g}{mol} * 2.8 {10}^{- 5} mol}{0.865 g \text{/} mL} = 2.98 μL$$

With 2.98 μL of toluene in a 0.02 L container at 25° C., the saturated point of toluene is achieved. If the amount of toluene is higher than 2.98 μL, not all toluene molecules are in gaseous phase and the GC signal of toluene will be constant if a small amount of toluene is absorbed by CD, as the surplus toluene will then go in gas phase. Therefore less than 2.98 μL of toluene was used in the gas chromatography experiment and in regard other volatile guest molecules the saturation limit was also calculated by means of Equation 2 and Equation 3.

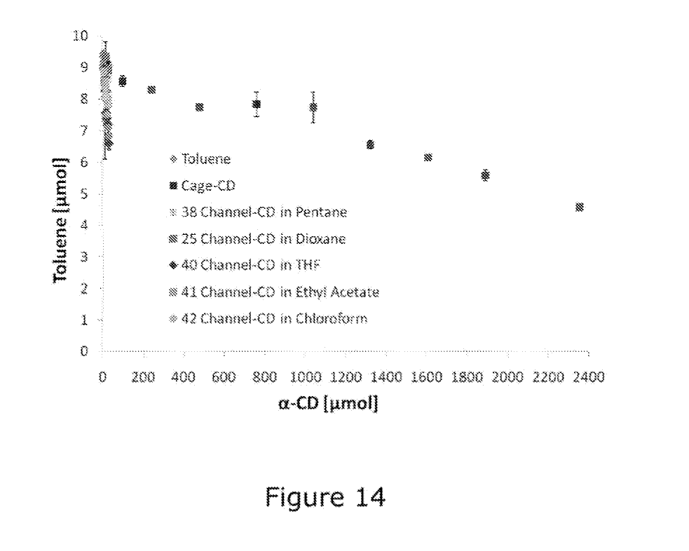

1 μl (9.4 μmol) of toluene was used in the experiment with results shown in FIG. 14, in order to investigate the absorption of cage and channel type α-CD crystals. With 1 μl toluene, the headspace pressure is much lower than the saturated headspace pressure of toluene in the vial. The small amount of guest molecule gave a deviation during addition of guest due to difficulty of adding the small amount. However, a large amount of guest would require a larger amount of CD and the measurement was repeated three times to insure the results are accurate and reproducible and the standard deviation are shown in almost all the figures in this section. With a larger amount of CD in each vial the amount of CD needed for each experiment would increase a lot and at the same time the amount of toluene cannot be increased more than 3 times before liquid toluene would be present in the vial due to the headspace pressure.

The standard curve of toluene was used to determine the concentration in the headspace volume of the vials containing cage or channel type CD crystals as a function of the FID signal. Cage and channel type α- and γ-CD crystals were investigated for their ability to absorb toluene with increasing amount of CD crystals, as seen in FIG. 14 to FIG. 16. The channel type CD crystals have more available cavities than cage crystals as shown by Kida et al. 2008 therefore it is expected that channel type CD crystals are more effective in removal of toluene from gas phase. Toluene in gas phase is expected to form an inclusion complex with solid CD crystals and the effect of cage and channel type α-CD crystals on the amount of toluene guest in headspace can be seen in FIG. 14.

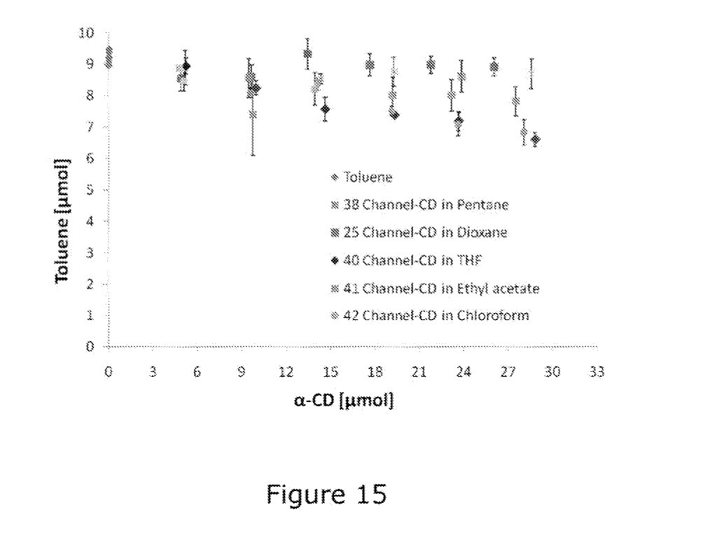

As seen in FIG. 14, the cage type α-CD crystal is able to remove some toluene when using very large amounts of CD. Similar results can be obtained using a very small amount of channel type crystal. The starting amount of toluene was 9.4 μmol in all measurements. By using around 2400 μmol of cage type α-CD crystals, the amount of toluene is reduced to 4.5 μmol; therefore 4.9 μmol of toluene was absorbed by 2400 μmol cage CD. The channel type α-CD crystals were used in much less amounts where the highest amount of channel crystals used was 30 μmol, i.e. a factor of 80. A higher absorption efficiency of channel type α-CD crystal can easier be seen in FIG. 15.

The absorption ability of channel type α-CD crystals depends on which solvent was used for production. The absorption ability from best to worst of the channel crystals is in the order: chloroform, THF, ethyl acetate, pentane, and dioxane. Product 41 produced in ethyl acetate contain both cage and channel crystals, but its absorption ability is still better than product 25 and 38 which contain only channel crystals. This phenomena show that the solvent used during production is an important factor for the absorption because solvent is still present in the product. It is believed, some guest molecules interact more strongly with CD cavities than other guest molecules. Pentane and dioxane might fit better in α-CD cavities resulting in a limitation for the diffusion of toluene into the CD channels. Therefore, the competition between toluene and the solvent molecule is an important factor as well as the volatility of the solvent when it is displaced from the cavity. If solvent molecules interact with the CD cavity better than the volatile guest molecules, the absorption ability will be low. Another factor is the amount of solvent molecules in the cavity. This aspect is elucidated by product 25 which only contains channel crystals but still have lower adsorption capabilities than the other products. It is believed that this is because product 25 contains a lot of dioxane in the cavities, as indicated from in Table 12.

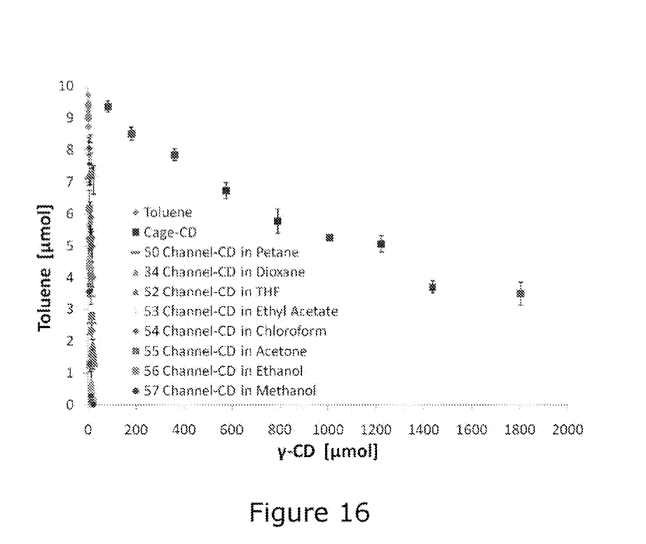

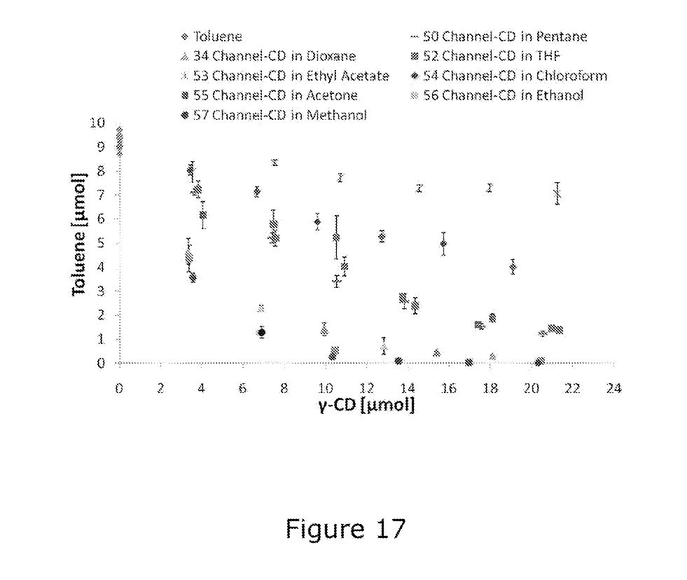

The best α-CD product for toluene absorption is product 38, produced in pentane, since 30 μmol of product 38 could remove approximately 3 μmol toluene, i.e. molar complexation ratio of 1:0.1. In regards to an aromatic ring like toluene, the complexation ratio is expected to be 1:1 which corresponds to a molar complexation ratio of 1 if a guest-host complex is established with all available cavities. An explanation as to why both cage and channel α-CD crystals are ineffective at removing toluene, is that the toluene molecule is too wide compared to the α-CD cavity. A bigger cavity like γ-CD cavity may be better at removing toluene from gas phase. Therefore, cage and channel type γ-CD crystals were also tested with toluene and their absorption is shown in FIG. 16 and FIG. 17.

In FIG. 17, the absorption ability of the products is in the order from best to worst: methanol, ethanol, dioxane, pentane, acetone, THF, chloroform, and ethyl acetate. Product 53 produced in ethyl acetate has the worst absorption capability, which may be due to the presence of both cage and channel crystal structure in the final product (both a big cage and channel peak is present in its diffractogram). Product 54, produced in chloroform, contains only channel type CD crystals; whereas product 50 and 52 contains a small amount of cage crystal although their absorption abilities are still better than product 54. Product 54 has a small amount of solvent but a lot of water (12 mol water for 1 mol CD) compared to the other products. It could be that the large amount of water might limit toluene from forming complex with the CD cavity. If the cavity has a lot of water that needs to be displaced the water has to go into vapor phase in order to escape the crystals. This takes energy and therefore the release of a large quantity of water from CD channels is difficult due to the high vapor pressure (compared to many of the solvents). Product 56 and 57, produced in ethanol and methanol, respectively, are the best absorbents. Product 57 contains the largest amount of solvent in the cavity compared to the other products, but methanol is very volatile and more polar than toluene. For that reason, methanol is easily displaced from the cavity by toluene, where the displacement gives a release of energy and only a small amount of energy is used to get methanol into the gas phase due to the low vapor pressure. The absorption ability of product 56 is almost similar to product 57 however the release of ethanol to the nearby environment during absorption of toluene is completely non-harmful. The great absorption capability of product 56 along with the solvent being Ethanol makes the production of channel type γ-CD crystals more interesting and appealing in the future as channel type CD crystals show unique properties which the cage type CD crystals do not have.

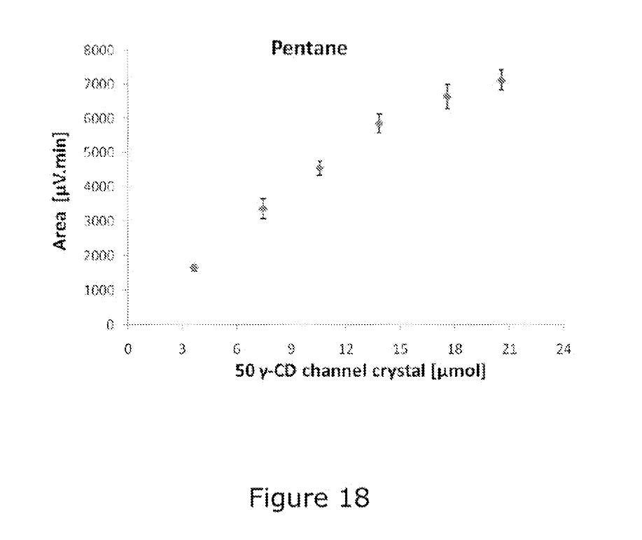

Solvent residue from the product was released during absorption as a consequence of the absorption of volatile guest molecule. The signal of residue solvent was increased in the chromatograms as a function of the amount of absorbed toluene. The signal of pentane residue from product 50 is shown in FIG. 18 as a representative sample of the measured products.

Increasing the amount of product 50 added in a vial, more pentane was released into gas phase, resulting in more available CD channels. The increased pentane concentration in the gas phase is most likely a combination of more CD which can release pentane due to a larger surface area for evaporation as well and a consequence of the increased toluene adsorption which displaces more pentane from the cavities. Therefore the solvent used in the precipitation process has a limited effect of the absorption capabilities of the crystals as long as the solvent is highly volatile as it is then easily displaced by a guest molecule.

The channel type CD crystals were able to absorb volatile guest molecules with a molar complexation ratio of 1:0.7, however, the size and structure of a guest molecule is a significant factor and determines the selectivity of channel type CD crystals because the absorption corresponds to an inclusion of guest molecule in the cavities of channel type CD crystals.

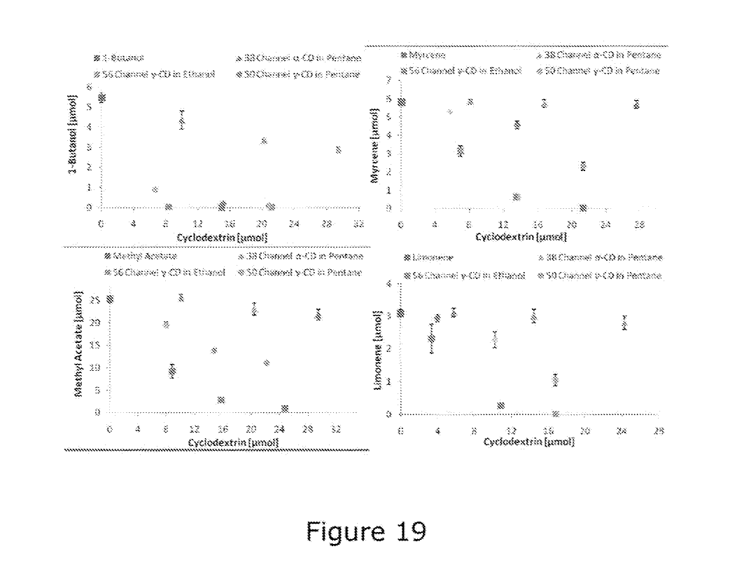

The selectivity of channel type CD crystals was tested with four different volatile guest molecules, as seen in FIG. 19. The channel type crystals of α- and γ-CD produced in pentane were used to investigate the difference in selectivity of channel type CD crystals. Channel type γ-CD crystals obtained in pentane and ethanol were used to investigate the effect of solvent used for precipitation on the absorption ability.

Different amount of guest molecules were used to test the selectivity of channel type CD because each guest molecule has a different saturated headspace pressure and different size.

The γ-CD products, no matter in which solvent they were produced, are better for absorption of the four compounds tested than the α-CD product. The difference between α-CD and γ-CD channel crystals is the size of cavity. It means that α-CD channel crystals are limited to absorbing volatile guest molecules such as aromatic and monocyclic compounds e.g. toluene and limonene, or rigid linear compounds like myrcene. For a small and more flexible molecule, such as methyl acetate and 1-butanol, α-CD channel crystal has a better absorption but the molar complexation is far from a 1:1 ratio. It is speculated that even smaller hydrophobic guest molecules will be better absorbed by the channel type α-CD crystals.

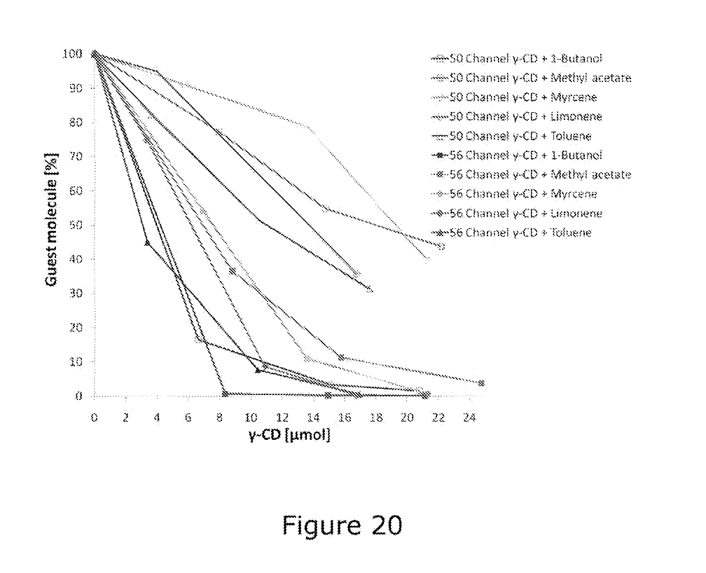

Product 56 absorbed different amounts of guest depending on the guest compound. The selectivity of channel type γ-CD crystals can be elucidated with a coarse calculation of the molar absorption. The molar complexation ratio between product 56 and 1-butanol, methyl acetate, myrcene, and limonene is 1:0.65, 1:1.02, 1:0.38, and 1:0.26, respectively. The molar complexation ratio of limonene by CD channel crystals is the least effective. It makes sense because limonene has the largest structure compared to the remaining guest molecules. The smallest guest molecule is methyl acetate, which results in the highest molar absorption. 1-butanol molecule is a bit larger than methyl acetate but it has more flexible structure there the molar complexation ratio is close to the highest. Generally, the bigger or the more rigid the structure, the poorer channel crystals absorb the guest molecule. The selectivity can be further evaluated from FIG. 20 and FIG. 21.

Product 50 and 56 clearly show an ability to absorb guest compounds. The guest compound is absorbed in larger quantity by product 56 than product 50. With only 8 μmol of product 56, 55-100% of the guest molecules were removed whereas product 50 only removed 15-40% with the same amount of CD, except 1-butanol where 85% or 100% was removed from gas phase.

One of the reasons product 56 is better than product 50 is that pentane is more apolar than ethanol. Therefore pentane molecules have a higher stability constant with CD. The other factors that influence the ability to absorb guest molecules are the total amount of solvent and water present in the products and the size of the CD crystals. All the obtained products were grinded in an attempt to unify the crystal size but there was deviation of the particle size. Crystal size is a factor of the absorption because smaller crystals have a bigger surface area which will improve the absorption efficiency of almost any absorption material, including CD.

The selectivity of channel type α-CD crystals is very limited compared to channel type γ-CD crystals produced in the same solvent, as seen in FIG. 21.

When comparing the absorption of the channel type α-CD to the absorption of channel type γ-CD, the two different absorptions seem to be based on different mechanisms. For 1-buthanol both α-CD and γ-CD seem to form inclusion complex which leads to a good absorption of the compound. For the other guest molecules it seems that α-CD absorption is mostly a surface absorption, as very limited amount of guest molecule is removed with increasing amount of CD, whereas the γ-CD removes large amounts of guest with increasing amounts. Large guest molecules which do not fit into the α-CD cavity can easier fit the γ-CD and then form inclusion complexes, due to its bigger cavities which lead to the improved absorption. The channel type α-CD are still more efficient than cage type α-CD so it is believed there is some inclusion of the guest molecules, but clearly not a lot as the molar complexation ratio is very low.

### Example 11

### Gas Chromatography—Adsorption Ability Test

A Varian 450 GC equipped with flame ionization detector (FID) was used to investigate the property and selectivity of the cage and channel type α-, and γ-CD crystals. Five different compounds were used as model guest molecules: an aromatic hydrocarbon (Toluene), a monocyclic monoterpene (D-Limonene), a linear terpene (β-Myrcene), an ester (Methyl Acetate), and a primary alcohol (1-Butanol). Each guest compound was measured with a unique GC program. The common setting used for all model guests were injection and detector temperature of 250, where helium as carrier gas. A column flow of 1.3 mL/min was used in all samples, and the column used was a Forte GC capillary Column from SGE analytical science with length of 30 m, internal diameter of 0.25 mm, and the film layer thickness of cyanopropylphenyl polysiloxane on the column wall is 1.4 μm. For sample injection, a Combipal (CTC, Switzerland) auto sampler equipped with a 2 ml temperature controlled headspace needle was used. The syringe and incubation temperature were kept at 35° C. The carrier gas flow of He was 25 mL/min where the combustion gases H₂ and air had a flow of 30 mL/min and 300 mL/min, respectively.

The samples were analyzed by adding a certain amount of cage or channel CD crystals to a 20 ml headspace vial after which the model guests were added onto the side of the vial, in order to avoid direct contact between the CD and the liquid guest. The headspace vials were sealed and left for at least 3 or 18 hours for the channel type CD and cage type CD, respectively, in order to obtain equilibrium. Prior to sampling, the headspace vial was moved to the agitator where it was shaken at 500 rpm for 4 minutes. Then 300 μl of headspace volume was injected into the GC. However for the kinetic experiment, the headspace vial was only shaken for 30 seconds. All measurements were repeated with three vials to insure reproducibility.

The calibration curve was produced with seven vials containing toluene amounts of 0.2, 0.5, 0.8, 1.1, 1.4, 1.7, and 2.0 μL. The calibration curve was used to calculate the relationship between the concentration in the headspace volume of toluene and the FID signal, and afterwards used to determine the amount of absorbed toluene. The temperature program for the column for all the guest molecules are shown in Table A.

TABLE A
The temperature program in the column and split ratio depends
on the added guest molecules. The first isothermal time is the
duration at the starting temperature and the last isothermal time
is the duration the oven is kept at the final temperature.

| Temperature | Tolu- | Limo- | | Methyl | 1- | |
|---|---|---|---|---|---|---|
| program | ene | nene | Myrcene | Acetate | Butanol | Kinetic |
| Start Temp. | 80 | 80 | 80 | 70 | 80 | 80 |
| [° C.] | | | | | | |
| Isothermal time | | | | | | |
| [min] | 2 | 2 | 2 | 2 | 1 | 2 |
| Heating rate | 15 | 20 | 20 | 20 | 20 | 15 |
| [° C./min] | | | | | | |
| End Temp. | 200 | 200 | 200 | 150 | 160 | 180 |
| [° C.] | | | | | | |
| Isothermal | 2 | 4 | 4 | 0 | 0 | 4 |
| [min] | | | | | | |
| Split ratio | 30 | 10 | 10 | 40 | 20 | 30 |

### Example 12

### Investigating Absorption Kinetic of Cage and Channel Type γ-CD Crystals

The absorption ability of the channel type CD crystals has been proven to be much better than cage crystals, especially γ-CD. Nevertheless, the absorption kinetics is a very important factor for the efficiency of the channel crystals in order to have any industrial application, e.g. absorbing nuclear waste product, such as iodine 135 isotope, unwanted odor masking etc. For an efficient product, a rapid absorption is required because a slow process does not help to remove unwanted compound in gas phase before they are released to the surrounding environment.

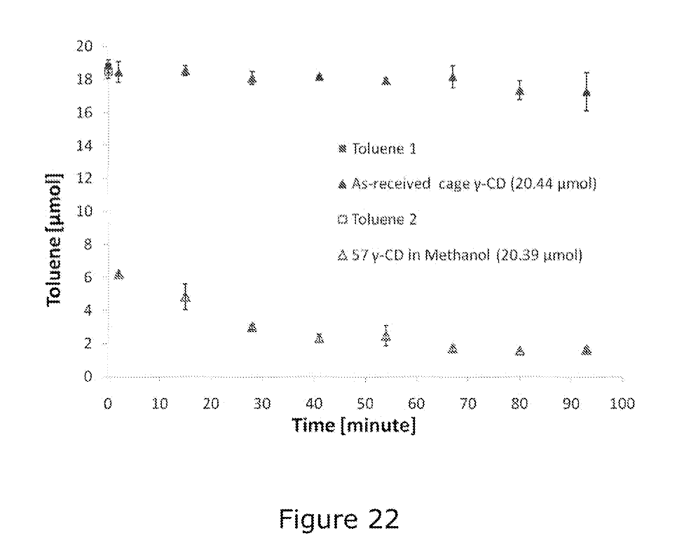

The absorption rate was therefore tested for both cage and channel type γ-CD crystals. The amount of CD crystals and toluene used was around 20 μmol and 19 μmol, respectively, as seen in FIG. 22. Faster sampling was desired, but due to the incubation time, oven temperature program and the speed of the CTC auto sampler, it was difficult to obtain a better sampling frequency.

In order to compare the absorption kinetic between cage and channel crystals, the amount of cage and channel γ-CD used have to be identical and the amount of toluene was constant in all the experiments. The amount γ-CD of cage and channel crystal shown in FIG. 22 is almost the same, 20.44 μmol of cage type γ-CD and 20.39 μmol of channel type γ-CD and for each data point 3 vials with γ-CD was measured. A total of 24 vials were tested for each crystal type γ-CD.

The reduction of toluene due to cage and channel type γ-CD crystals is completely different in the time range from 0 to 93 minutes. The amount of toluene is reduced very slowly by cage type γ-CD. After 93 minutes, the starting toluene of 19 μmol was reduced to 18 μmol, with only about 1 μmol toluene removed from gas phase. However, the deviation of the last data point of cage type γ-CD is higher than 1 μmol of toluene as shown by the standard deviation. Close to 200 μmol of cage type γ-CD could remove just over 1 μmol toluene in equilibrium state (time independent), as can also be seen in FIG. 16.

The channel type γ-CD crystals reduced 19 μmol toluene to 6 μmol after 2 minutes, which is a molar complexation ratio of 1:0.64. It is an extremely fast absorption of channel type CD compared to cage structure. After the initial absorption the channel type γ-CD did not absorb much, and after 65 minutes it seems an equilibrium state was achieved. After 65 minutes, 20.39 μmol channel type γ-CD had removed around 17 μmol toluene from gas phase corresponds which gives a molar complexation of 1:0.83. When comparing the absorption of the same product (product 57) in the equilibrium state, the vial containing around 10.3 μmol of product 57 and 9.4 μmol toluene was left for 3 hours. The amount of toluene was reduced to about 0.2 μmol, corresponding to molar complexation ratio of 1:0.89. The molar complexation ratio after 65 minutes (1:0.83) and 3 hour (1:0.89) is almost the same which means the equilibrium state was obtained after 65 minutes.

### Example 13

### Iodine Absorption by Cage and Channel Type α- and γ-CD Crystals

Iodine 135 isotope is a nuclear waste product from the fission process of uranium 235 isotope, and the successful iodine entrapment of CD in aqueous solution can prevent the spreading of nuclear contaminant which makes the uptake of iodine interesting. Therefore the absorption ability of channel type CD crystal in regards to iodine in gas phase was investigated as a new technique for removal of iodine.

α-, β-, and γ-CD have earlier been shown to form inclusion complex with iodine in water.

Channel type CD crystals were proven by the inventors to have great absorption ability in the gas phase, as well as high absorption kinetic. If the ability can be applied for removal of iodine, the problem with nuclear waste treatment of iodine or with iodine radiation in the atmosphere can be helped greatly. Therefore the absorption of iodine by cage and channel type CD crystals in gas phase was investigated.

The spectra of iodine and complex iodine/CD were tested before the absorption experiment was performed because iodine has a very strong colour, where a small amount of iodine might give a very high absorbance, which might be due to the shielding of iodine molecules in the solution, resulting in the wrong absorbance. Therefore a suitable concentration of iodine should be found in order to establish an iodine calibration curve used for further calculation of the iodine removal by CD crystals.

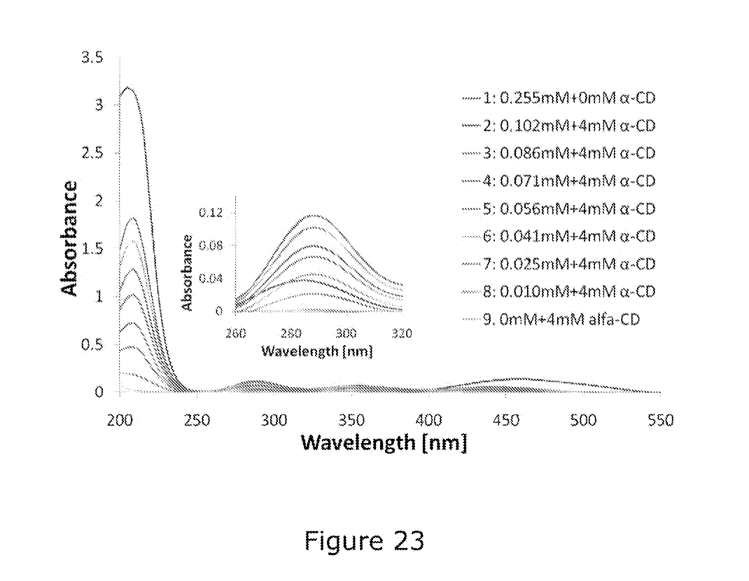

In FIG. 23, the spectra of 4 mM α-CD with different concentration of iodine are shown. The broad peak around 280 nm belongs to α-CD complexes because the peak appeared only after addition of CD. The absorbance shows a peak at 210 nm where a higher iodine concentration gives a greater absorbance, therefore the peak at 210 nm seems to belong to free iodine. Spectrum 1 belongs to the solution with the highest concentration of iodine but without α-CD where free iodine shows high absorbance at 210 nm and 460 nm. Spectra 2-9 in FIG. 23 show that the absorbance at 210 nm and 280 nm depend on the iodine concentration in solution.

Two calibration curves of iodine and α-CD were measured where both curves have constant α-CD concentration, one solution with 2 mM and the other with 4 mM. The concentration of α-CD is constant for each calibration curve, because more α-CD in solution should form more complex iodine/α-CD, resulting in an absorbance decrease of free iodine molecules. The calibration curves of iodine/α-CD are not shown.

The calibration curves are identical where it was expected the slope of the calibration curve having α-CD concentration of 2 mM was higher because of less complex formation with smaller α-CD concentration, meaning more free iodine in solution. The highest concentration of iodine is 0.127 mM whereas the α-CD concentration is 2 mM and 4 mM. The calibration curves seem to be independent of the α-CD concentration, which can be explained if the absorbance at wavelength 210 nm belongs to both free iodine and α-CD/iodine complex, and all iodine forms complex due to the low concentration of iodine compared to the α-CD concentration. Therefore the calibration curve is independent of the CD concentration (when CD is in surplus) and only depending on the iodine concentration.

The colour of cage crystals and product 39 depend on the amount of the absorbed iodine, but the strong purple colour was observed only for the product produced in pentane. Pentane residue from the product reacted with iodine and gives the purple colour as a separate experiment verified.

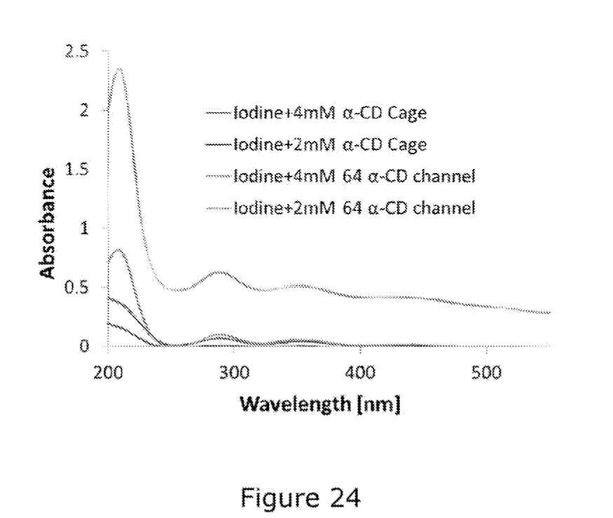

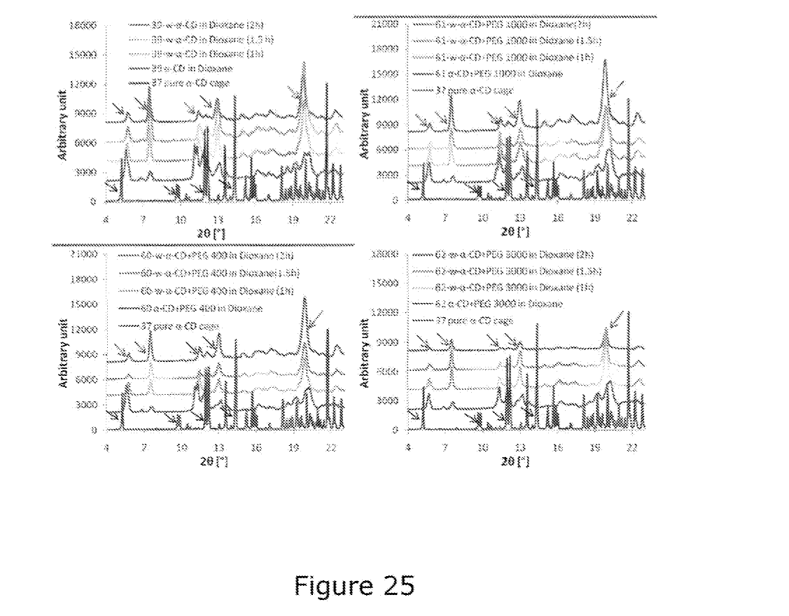

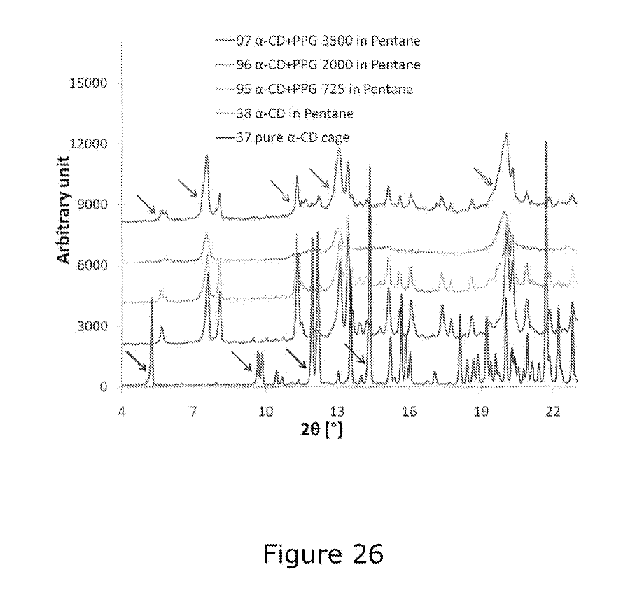

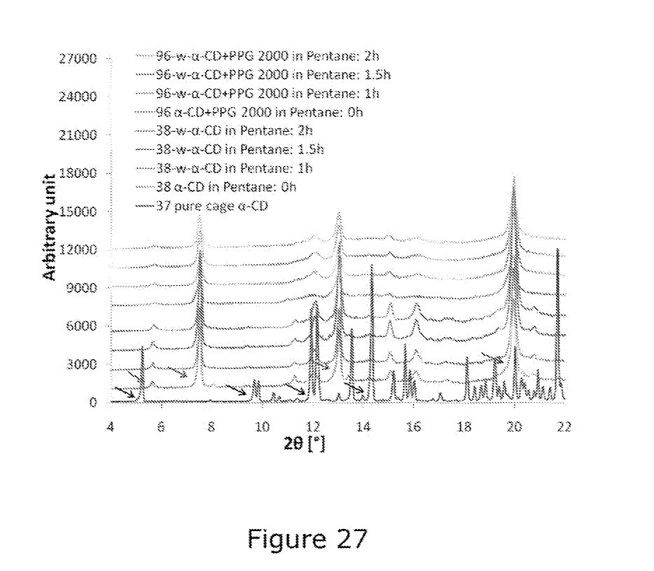

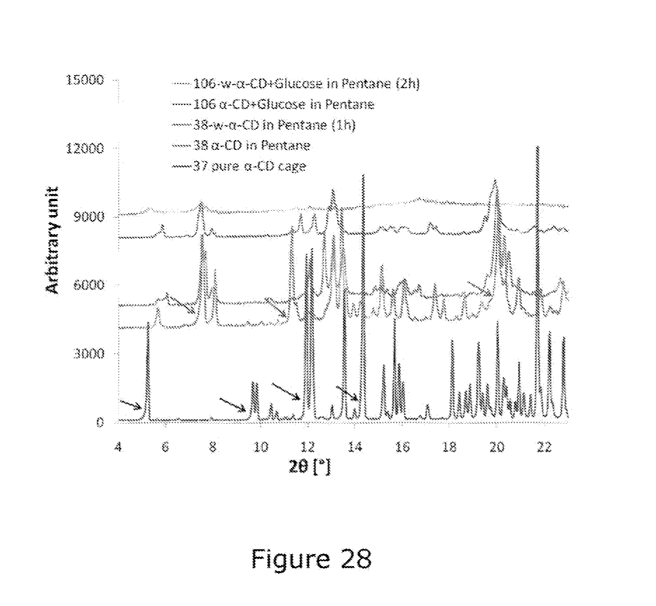

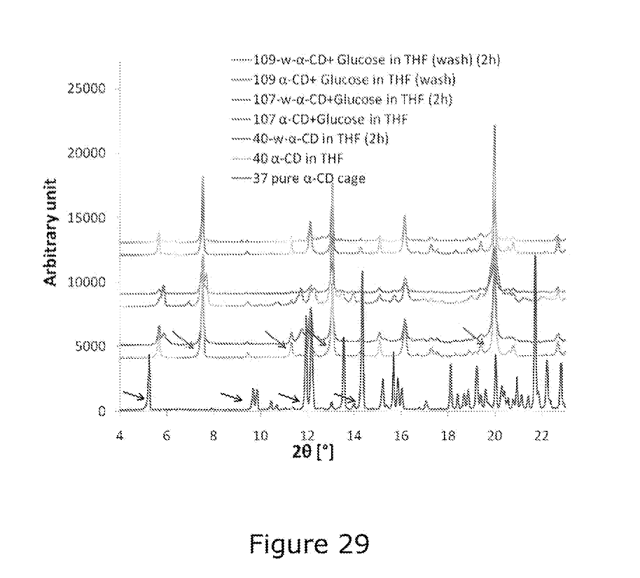

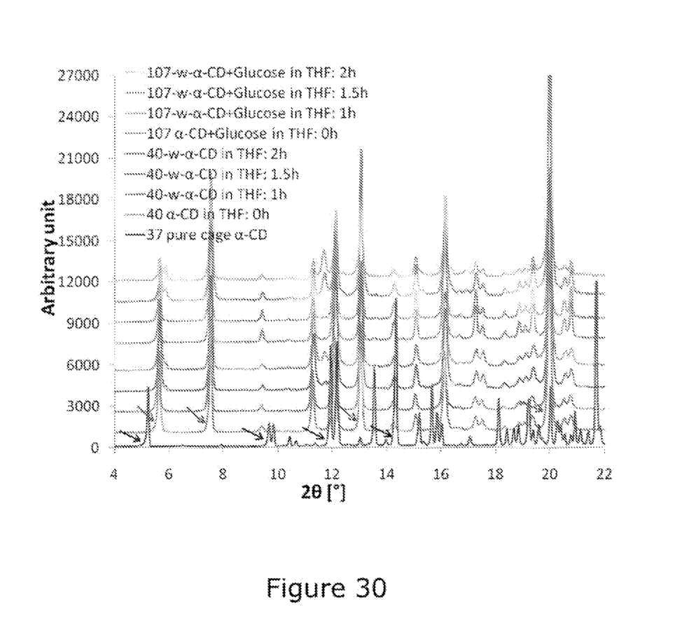

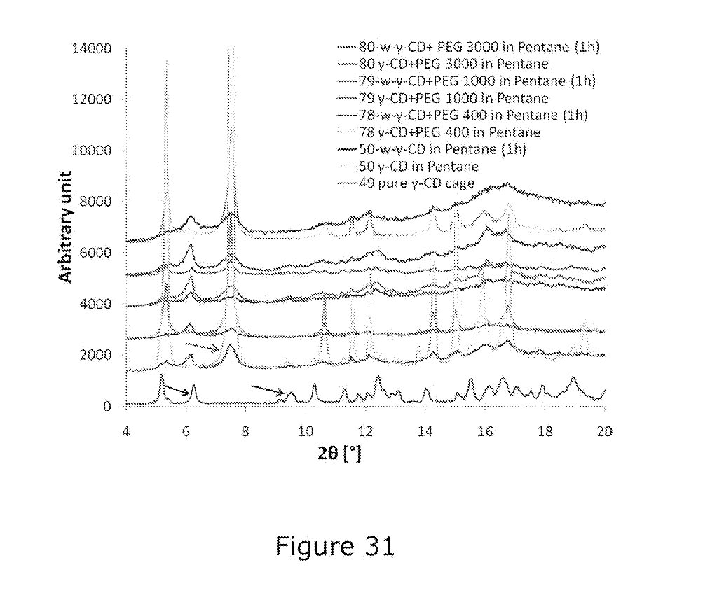

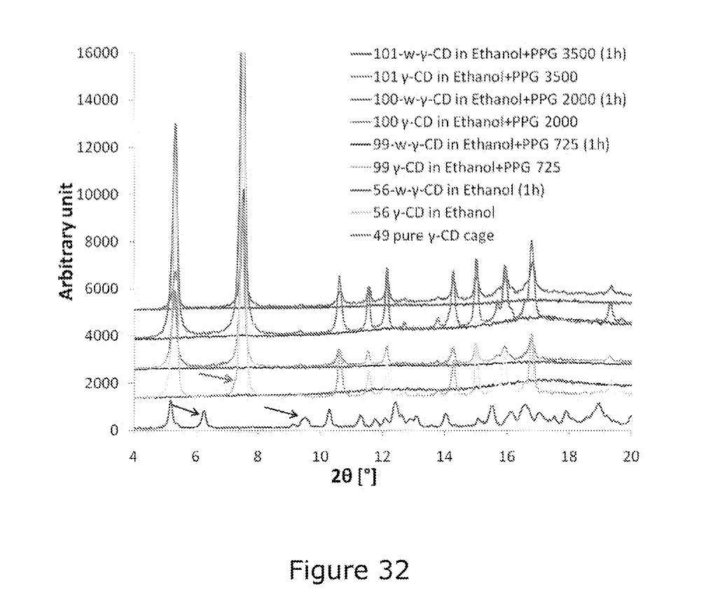

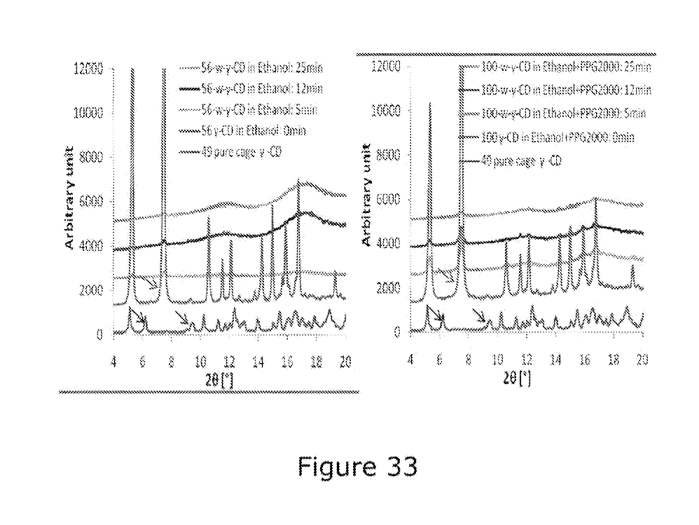

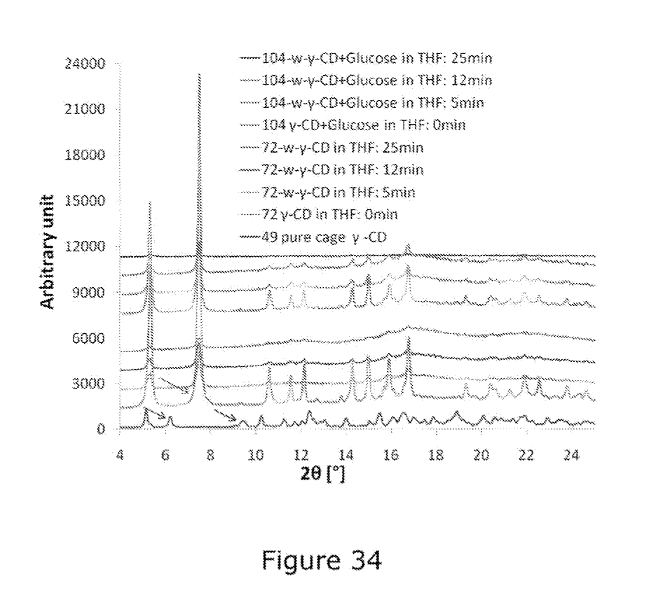

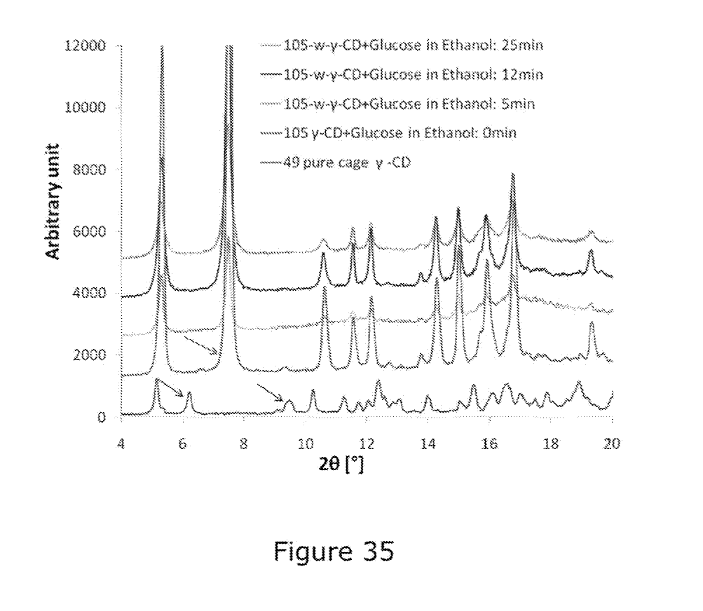

The powders of α-CD/iodine complex in the vials were dissolved with water to reach an α-CD concentration of 4 mM and then diluted to 2 mM. The dilution was done because the spectrum of the 4 mM α-CD/iodine solution from product 64 showed absorbance at all wavelengths, as seen in FIG. 24, and this is most likely due to scattering of light. The light scattering is normally due to small particles left in solution and it was expected that there particles were α-CD/iodine inclusion complex and therefore the solution was diluted to solvate the remaining inclusion complex.

The result of the iodine absorption of cage and channel type α-CD crystals is shown in Table 18. The absorption percent of iodine by CD calculated from the experiment where some scattering was observed is not accurate because of the light scattering, e.g. product 64 in experiment 1 could remove 111% iodine where 100% is total removal of all iodine added.

In the first experiment, the cage and channel type α-CD crystals could absorb 18% and 75% iodine after only 20 minutes. Less percent iodine was removed from gas phase in the second experiment; 54% by product 64 and 59% by product 25 both measured after 2 days. The absorption efficiency of product 64 in the first experiment is better than the same product in the second experiment because the ratio CD/iodine is 34:1 and 29:1 for the first and second experiment, another difference is whether the in crucible containing the iodine was closed or open. Diffusion of iodine from the opened Tin crucible is higher than the closed Tin crucible, resulting in increasing absorption efficiency of product 64. Product 39 produced in 1,4-dioxane absorbed iodine a little better than product 64 as seen in Table 18.

Based on the first experiment, which is more accurate than the second experiment, channel type α-CD absorbed iodine over 4 times better than cage crystals even though channel type α-CD produced in pentane is not the best absorbent compared to other product.

TABLE 18
After reacting with iodine in the vial, cage and
channel type a-CD powder were diluted to 4 mM and then 2 mM. The
absorbance of the solutions was measured. Percent amount of iodine
absorbed by cage and channel type α-CD crystal were calculated from
the two standard curves.

| | α-CD | | Absorption | |
|---|---|---|---|---|
| | [mM] | Iodine [mM] | [%] | Solution |
| 1. Experiment (20 | | | | |
| minutes) | | | | |
| As-received cage α- | 4 | 0.02 | 18 | Clear |
| CD | | | | |
| 64 Channel α-CD in | 4.02 | 0.13 | 111 | Cloudy |
| Pentane | | | | |
| As-received cage α- | 2 | 0.01 | 11 | Clear |
| CD | | | | |
| 64 Channel α-CD in | 2 | 0.04 | 75 | Clear |
| Pentane | | | | |
| 2. Experiment (two | | | | |
| days) | | | | |
| As-received cage α- | 4 | 0.03 | 25 | Clear |
| CD | | | | |
| 64 Channel α-CD in | 4 | 0.07 | 54 | A bit of |
| Pentane | | | | Cloudy |
| 39 Channel α-CD in | 3.8 | 0.07 | 59 | Clear |
| Dioxane | | | | |
| 64 Channel α-CD in | 2 | 0.04 | 54 | Clear |
| Pentane | | | | |
| 39 Channel α-CD in | 1.9 | 0.04 | 59 | Clear |
| Dioxane | | | | |

Based on the results, it was speculated that the α-CD/iodine complex is more stable than the γ-CD/iodine complex, since it took much longer time to dissolve the solid α-CD/iodine than the γ-CD/iodine solid. The absorption percent of iodine by cage type and channel γ-CD is shown in Table 19.

TABLE 19
After interacting with iodine in the vial, cage and
channel type γ-CD powder was diluted to concentration of 4 mM of CD
and then the absorbance of the solution was measured. Percent amount
of iodine absorbed by cage and channel type γ-CD crystal were
calculated from the standard curve and starting amount of iodine.

| 3. Experiment (20 | γ-CD | Iodine | Absorption | |
|---|---|---|---|---|
| minutes) | [mM] | [mM] | [%] | Solution |
| Cage γ-CD | 4.00 | 0.02 | 4 | Clear |
| 51 Channel γ-CD in | 4.00 | 0.12 | 27 | Clear |
| Dioxane | | | | |
| 52 Channel γ-CD in | 4.00 | 0.11 | 25 | Clear |
| THF | | | | |

Channel type γ-CD absorbed iodine absorbed over 6 times better than cage γ-CD but only around 25% iodine was removed from gas phase by γ-CD where 75% iodine was removed by α-CD. A molar ratio of γ-CD/iodine and α-CD/iodine of 9:1 and 34:1, respectively, was used. Although the percent absorption of the channel type γ-CD is lower than the channel type α-CD, the total amount of iodine absorbed was higher.

### Example 14

### Recycling of Channel Type CD Crystals

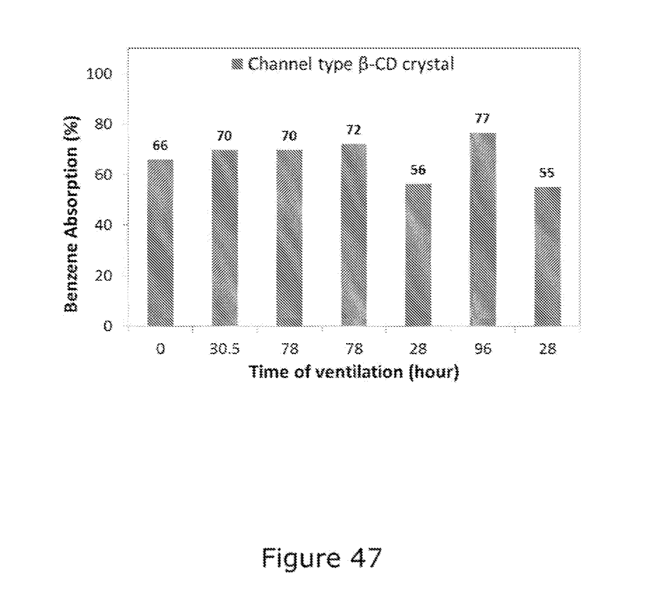

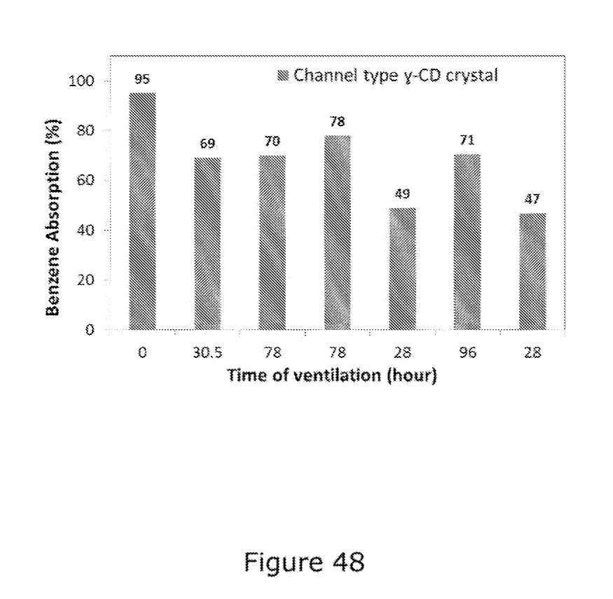

The absorption of channel β- and γ-CD with 3 μl (33.76 μmol) benzene in 20 mL vial was measured by using gas chromatography equipment. After each measurement, the channel CD crystals were ventilated and reused 7 times. The experimental results are shown in FIG. 47 and FIG. 48.

The experiment has shown the channel type cyclodextrin crystals can be re-used as absorbents after “ventilation” of the absorbed substances. The product is able to reduce the gas pressure because the crystals are out to the “open” air, they release the absorbed substances slowly and recreate the absorbing capacity.

### Example 15

### Triggered Release of Guest Molecules from Channel Type CD Crystals

An amount of channel β- and γ-CD crystals were divided into two parts, one is put in a container with saturated pressure of limonene and the other one kept free of guest molecules for 1 week. 20 mg of the channel crystals with and without limonene was weighted and transferred to 20 mL vials. The triggered release of limonene was measured after adding 2 μL toluene (18.78 μmol).

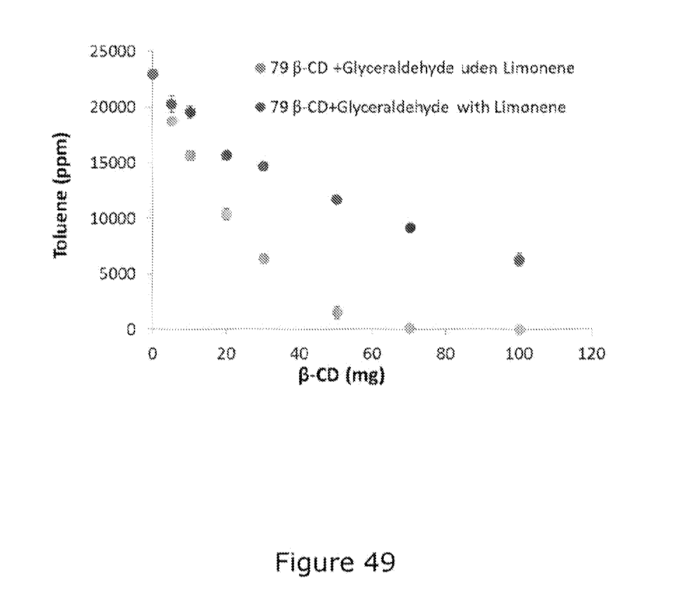

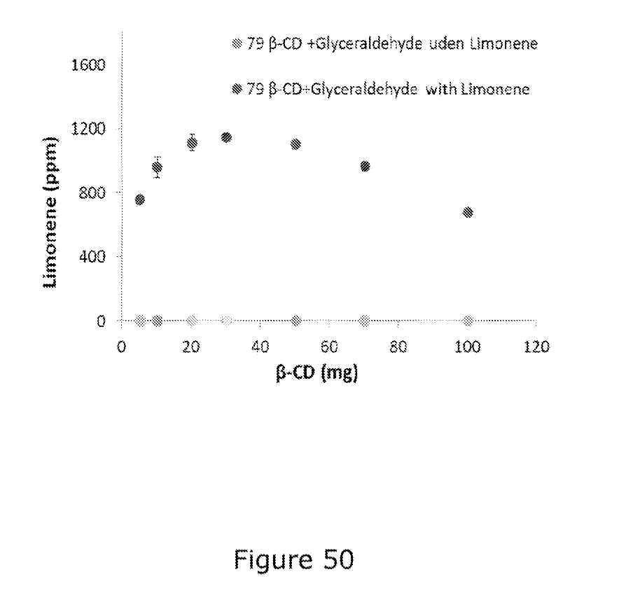

FIG. 49 shows how toluene is adsorbed by the CD crystals with and without the a limonene guest molecule, while FIG. 50 shows how limonene is released (triggered by the addition of toluene) from the CD crystals comprising limonene. The experiment has shown that it is possible to replace the absorbed substances with substances of similar or larger affinity for the crystals. This allows for the development of systems with controlled release of active substances.

### REFERENCES

Rusa, C. C.; Bullions, T. A.; Fox, J.; Porbeni, F. E.; Wang, X.; Tonelli, A. E. Langmuir 2002, 18, 10016.
Kida, T.; Nakano, T.; Fujino, Y.; Matsumura, C.; Miyawaki, K.; Kato, E.; Akashi, M. Anal. Chem. 2008, 80, 317.
Uyar, T.; El-Shafei, A.; Wang, X. W.; Hacaloglu, J.; Tonelli, A. E. J. Inclusion Phenom. Macrocyclic Chem. 2006, 55, 109.
Panova I G, Matuchina E V, Topchieva I N.; The template co-crystallization of beta-cyclodextrin with polymeric inclusion complex. Polym Bull 2007 APR; 58(4):737-746.

1. A method for producing channel type cyclodextrin crystals comprising the steps of:
a) Providing a solution of cyclodextrin;
b) Contacting said solution with a non-solvent system having a Snyder polarity index (P′) of less than 5.4 to precipitate channel type cyclodextrin;
c) Separating said precipitated channel type cyclodextrin from the solution and non-solvent system;
provided that when the cyclodextrin is an α-cyclodextrin, and when the non-solvent system does not comprise an alcohol, the non-solvent system has a relative polarity of less than 0.229;
provided that when the cyclodextrin is an β-cyclodextrin, and when the non-solvent system does not comprise an alcohol, the non-solvent system has a relative polarity of less than 0.164;
provided that when the cyclodextrin is a γ-cyclodextrin, the non-solvent system is selected from the group consisting of ethanol, 1-propanol, 1-butanol and mixtures thereof.

2. The method according to claim 1, wherein the solution of cyclodextrin contains water.

3. The method according to claim 1, wherein the solution of cyclodextrin is an aqueous solution of cyclodextrin.

4. The method according to claim 1, wherein the cyclodextrin is an α-cyclodextrin and the non-solvent system is selected from the group consisting of pentane, hexane, heptane, cyclohexane, ethanol, 1-butanol, 1-propanol, THF, ethyl acetate, 1,4-dioxane and mixtures thereof.

5. The method according to claim 1, wherein the cyclodextrin is a β-cyclodextrin and the non-solvent system is selected from the group consisting of pentane, hexane, heptane, cyclohexane, ethanol, 1-propanol, 1-butanol and mixtures thereof.

6. The method according to claim 1, wherein the non-solvent system comprises a triglyceride.

7. The method according to claim 1, wherein the non-solvent system is a vegetable oil.

8. The method according to claim 1, wherein the temperature of the solution of cyclodextrin is equal to or higher than a temperature of the non-solvent system.

9. Channel type cyclodextrin crystals obtainable by the method according to claim 1.

10. A channel type β-cyclodextrin crystal characterised by at least the following X-ray powder diffractogram reflexes:

| Angle | Rel. int |
|---|---|
| [°] | [%] |
| 6.21 | 66.4 |
| 7.24 | 100.0 |
| 9.74 | 19.7 |
| 10.09 | 53.2 |
| 11.96 | 51.3 |
| 12.22 | 45.5 |
| 18.80 | 43.8 |

11. A channel type β-cyclodextrin crystal according to claim 10 having an x-ray diffraction pattern essentially as shown in FIG. 51.

12. A plastic product comprising the channel type cyclodextrin crystals according to claim 9.

13. A fiber comprising channel type cyclodextrin crystals according to claim 9.

14. (canceled)

15. A thermoplastic polyester container comprising a thermoplastic polyester and a channel type cyclodextrin crystal according to claim 9.

16. A filter material comprising channel type cyclodextrin crystals according to claim 9.

17. A filter mask comprising channel type cyclodextrin crystals according to claim 9.

18. A packaging material comprising channel type cyclodextrin crystals according to claim 9.

19. An aroma barrier comprising channel type cyclodextrin crystals according to claim 9.

20-28. (canceled)
